(19) United States
(12) Patent Application Publication
(10) Pub. No.: US 2026/0052840 A1
(43) Pub. Date: Feb. 19, 2026

(54) DISPLAY DEVICE AND ELECTRONIC DEVICE INCLUDING THE SAME

(71) Applicant: Samsung Display Co., Ltd., Yongin-si (KR)

(72) Inventors: Jongwoo JIN, Yongin-si (KR); YEONHONG KIM, Yongin-si (KR); MYOUNGHWA KIM, Yongin-si (KR); YEON KEON MOON, Yongin-si (KR); JUN HYUNG LIM, Yongin-si (KR)

(73) Assignee: Samsung Display Co., Ltd., Yongin-si (KR)

(21) Appl. No.: 19/272,251

(22) Filed: Jul. 17, 2025

(30) Foreign Application Priority Data
Aug. 16, 2024 (KR) 10-2024-0109788

(51) Int. Cl. H10K 59/121; H10K 59/131

(52) U.S. Cl. CPC H10K 59/1213; H10K 59/131

(57) ABSTRACT

Provided is a display device including a circuit layer including a first transistor, a second transistor disposed on the first transistor, and a conductive pattern disposed between the first transistor and the second transistor, and a display layer disposed on the circuit layer and including a light emitting element, wherein the first transistor includes a first semiconductor pattern and a first upper electrode, the second transistor includes a second semiconductor pattern, a second upper electrode disposed on the second semiconductor pattern, and a lower electrode disposed below the second semiconductor pattern, the first semiconductor pattern and the second semiconductor pattern overlap, and the conductive pattern at least partially overlaps each of the first semiconductor pattern and the second semiconductor pattern, and accordingly, the display device may exhibit minimized dead space and excellent driving characteristics.

### CROSS-REFERENCE TO RELATED APPLICATION(S)

This application claims priority to and benefits of Korean Patent Application No. 10-2024-0109788 under 35 U.S.C. § 119, filed on Aug. 16, 2024, the entire contents of which are incorporated herein by reference.

### BACKGROUND

### 1. Technical Field

The disclosure herein relates to a display device, and more particularly, to a display device including multiple transistors disposed on different layers and overlapping one another.

### 2. Description of the Related Art

Display devices are used in various multimedia devices such as television sets, mobile phones, tablet computers, and game consoles to provide image information to users. The display devices include light emitting elements and pixel circuits for driving the light emitting elements. The display devices include gate driving circuits for providing signals to the pixel circuits. The light emitting elements are controlled to emit light through signals output from the gate driving circuits.

Disposing these circuits may lead to an increase in dead space corresponding to a non-display region. Therefore, there is a need to develop a technology capable of adjusting the arrangement of circuits to reduce dead space and maintain superior electrical characteristics.

### SUMMARY

The disclosure provides a display device that reduces a non-display region by disposing a plurality of transistors to overlap on different layers.

The disclosure also provides a display device that exhibits excellent driving characteristics while minimizing a circuit layout area by disposing a conductive pattern between two transistors disposed to overlap in a plan view.

An embodiment of the disclosure may provide a display device including a base layer, a circuit layer disposed on the base layer and including a first transistor, a second transistor disposed on the first transistor, and a conductive pattern disposed between the first transistor and the second transistor, and a display layer disposed on the circuit layer and including a light emitting element, wherein the first transistor includes a first semiconductor pattern and a first upper electrode disposed on the first semiconductor pattern, the second transistor includes a second semiconductor pattern, a second upper electrode disposed on the second semiconductor pattern, and a lower electrode disposed below the second semiconductor pattern, the first semiconductor pattern and the second semiconductor pattern overlap, and the conductive pattern at least partially overlaps each of the first semiconductor pattern and the second semiconductor pattern.

In an embodiment, at least one of the first semiconductor pattern or the second semiconductor pattern may include an oxide semiconductor.

In an embodiment, the oxide semiconductor may have a mobility of about 20 cm²/Vs or greater.

In an embodiment, the oxide semiconductor may be a metal oxide containing indium, gallium, and zinc, and the content of indium in the metal oxide may be at least twice the content of gallium.

In an embodiment, at least one of the first semiconductor pattern or the second semiconductor pattern may be stacked in a thickness direction and may include a plurality of layers having different oxide semiconductor material compositions.

In an embodiment, the conductive pattern may include a metal, a metal oxide, or a transparent conductive material.

In an embodiment, the conductive pattern may be electrically connected to a constant voltage line, and the lower electrode may be electrically connected to the second semiconductor pattern or the second upper electrode.

In an embodiment, the conductive pattern may include a lattice pattern including a horizontal line portion extending in a direction in a plan view and a vertical line portion crossing the horizontal line portion.

In an embodiment, at least one hole may be defined in the conductive pattern.

In an embodiment, the circuit layer may further include a first insulating layer covering the first semiconductor pattern, a second insulating layer disposed between the first insulating layer and the conductive pattern, a third insulating layer disposed between the conductive pattern and the lower electrode, a fourth insulating layer covering the lower electrode, a fifth insulating layer covering the second semiconductor pattern, and an upper insulating layer disposed on the fifth insulating layer.

In an embodiment, a hole region may be defined as passing through from any one of the first to fourth insulating layers to the fifth insulating layer, and the upper insulating layer may be filled in the hole region.

In an embodiment, at least one of an upper surface of the second insulating layer or an upper surface of the third insulating layer may be a flat surface.

In an embodiment, the conductive pattern may be provided in plurality distinguished from one another, and the plurality of conductive patterns may be disposed to be spaced apart in a plan view, and each of plurality of the conductive patterns may be electrically connected to a different constant voltage line.

In an embodiment, a constant voltage may be applied to the conductive pattern, and the conductive pattern may be electrically connected to at least one of the first semiconductor pattern or the second semiconductor pattern.

In an embodiment, the circuit layer may further include a capacitor including a first sub-conductive pattern, and a second sub-conductive pattern overlapping the first sub-conductive pattern and disposed above or below the first sub-conductive pattern, the first sub-conductive pattern and the conductive pattern may be disposed on a same layer, and the first sub-conductive pattern and the conductive pattern may include a same material.

In an embodiment of the disclosure, an electronic device divided into a display region and a non-display region disposed on a side of the display region may include a base layer, a display layer disposed on the base layer and including a plurality of light emitting elements corresponding to the display region, and a circuit layer disposed between the base layer and the display layer and including a plurality of transistors and a plurality of insulating layers, wherein the circuit layer includes a pixel circuit electrically connected to the light emitting elements, and a gate driving circuit disposed in the non-display region and including a lower transistor, an upper transistor disposed on the lower transistor, and a conductive pattern disposed between the lower transistor and the upper transistor, the lower transistor includes a first semiconductor pattern and a first upper electrode disposed on the first semiconductor pattern, the upper transistor includes a second semiconductor pattern, a second upper electrode disposed on the second semiconductor pattern, and a lower electrode disposed below the second semiconductor pattern, the first semiconductor pattern and the second semiconductor pattern overlap, and the conductive pattern at least partially overlaps each of the first semiconductor pattern and the second semiconductor pattern.

In an embodiment, at least one of the first semiconductor pattern or the second semiconductor pattern may include a metal oxide containing at least one of indium, gallium, zinc, tin, or titanium.

In an embodiment, the pixel circuit may include a driving transistor including a third semiconductor pattern, and a switching transistor including a fourth semiconductor pattern that is distinguished from the third semiconductor pattern, and at least one of the third semiconductor pattern or the fourth semiconductor pattern may include a metal oxide containing at least one of indium, gallium, zinc, tin, or titanium.

In an embodiment, the first semiconductor pattern, the third semiconductor pattern, and the fourth semiconductor pattern may be disposed on a same layer.

In an embodiment, the third semiconductor pattern and any one of the first semiconductor pattern or the second semiconductor pattern may be disposed on a same layer, the fourth semiconductor pattern may overlap the third semiconductor pattern and be disposed above or below the third semiconductor pattern, and the circuit layer may further include a pixel portion conductive pattern disposed between the third semiconductor pattern and the fourth semiconductor pattern.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic perspective view of an electronic device according to an embodiment;

FIG. 2 is a schematic cross-sectional view of an electronic device according to an embodiment;

FIG. 3 is a schematic plan view of a display panel of an embodiment;

FIG. 4 is a schematic diagram of an equivalent circuit of pixels according to an embodiment;

FIG. 5 is a schematic diagram of an equivalent circuit of a gate driving circuit according to an embodiment;

FIG. 6 is a schematic cross-sectional view showing a portion of a display panel of an embodiment;

FIG. 7 is a schematic cross-sectional view showing a portion of a circuit layer according to an embodiment;

FIG. 8A is a schematic plan view showing a portion of a circuit layer according to an embodiment;

FIG. 8B is a schematic plan view showing a portion of a circuit layer according to an embodiment;

FIG. 9 is a schematic cross-sectional view showing a portion of a circuit layer according to an embodiment;

FIG. 10A is a schematic plan view showing a conductive pattern according to an embodiment;

FIG. 10B is a schematic plan view showing a conductive pattern according to an embodiment;

FIG. 11A is a schematic cross-sectional view showing a portion of a circuit layer according to an embodiment;

FIG. 11B is a schematic cross-sectional view showing a portion of a circuit layer according to an embodiment;

FIG. 12A is a schematic plan view showing a portion of a circuit layer according to an embodiment;

FIG. 12B is a schematic plan view showing a portion of a circuit layer according to an embodiment;

FIG. 13 is a schematic cross-sectional view showing a portion of a circuit layer according to an embodiment;

FIG. 14 is a schematic cross-sectional view showing a portion of a display panel according to an embodiment;

FIG. 15 is a schematic cross-sectional view showing a portion of a display panel according to an embodiment;

FIG. 16 is a schematic cross-sectional view showing a portion of a display panel according to an embodiment;

FIG. 17 is a block diagram of an electronic device according to an embodiment; and

FIG. 18 illustrates schematic views of an electronic device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

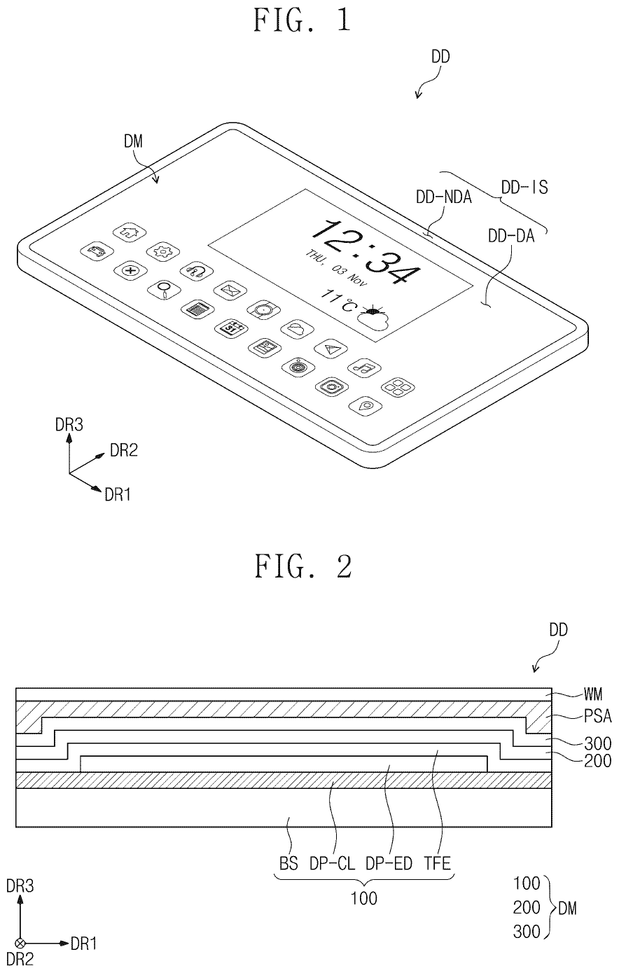

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure. FIG. 1 is a schematic perspective view of an electronic device DD according to an embodiment of the disclosure. As shown in FIG. 1, the electronic device DD may include a display device DM displaying images through a display surface DD-IS. In a plan view, the display surface DD-IS may have a rectangular shape which has long sides extending in a first direction DR1 and short sides extending in a second direction DR2 crossing the first direction DR1. However, the embodiment of the disclosure is not limited thereto, and the display surface DD-IS may have various shapes such as a circular shape or a polygonal shape.

Herein, a third direction DR3 may be defined as a direction substantially perpendicular to a plane defined by the first direction DR1 and the second direction DR2. A front surface (or upper surface) and a rear surface (or lower surface) of each member constituting the electronic device DD may oppose each other in the third direction DR3 and a normal direction of each of the front and rear surfaces may substantially be parallel to the third direction DR3. A distance between the front surface and the rear surface defined along the third direction DR3 may correspond to a thickness of a member.

Herein, the phrase “in a plan view” may be defined as a state viewed in the third direction DR3. For example, the phrase “in a plan view” may be described with respect to the plane defined by both the first direction DR1 and the second direction DR2. Herein, the phrase “on a cross-section” may be defined as a state viewed in the first direction DR1 or the second direction DR2. Meanwhile, directions indicated by the first to third directions DR1, DR2, and DR3 are relative concepts, and may thus be changed to other directions.

An electronic device DD including the display device DM provided with a flat display surface is shown in an embodiment of the disclosure, but the embodiment of the disclosure is not limited thereto. The electronic device DD may include a curved display surface or a three-dimensional display surface. For example, the three-dimensional display surface may include multiple display regions indicating different directions, and may also include a bent display surface. The electronic device DD according to the embodiment may be a flexible electronic device. The flexible electronic device may be a foldable electronic device.

In FIG. 1, a tablet terminal is shown as an example of the electronic device DD. The tablet terminal may be formed by placing electronic modules, camera modules, power modules, and the like mounted on a motherboard in a bracket/case along with the display device DM. Meanwhile, the embodiment of the disclosure is not limited thereto, and the display device DM may not only be used for large-sized electronic devices such as television sets and monitors but also used for small- and medium-sized electronic devices such as mobile phones, car navigation systems, game consoles, and smart watches.

As shown in FIG. 1, the display surface DD-IS may include an active region DD-DA on which images are displayed and a bezel region DD-NDA adjacent to the active region DD-DA. The bezel region DD-NDA is a region on which images are not displayed. In FIG. 1, icon images are shown as an example of images. The active region DD-DA may be referred to as a display region of the display device DM, and the bezel region DD-NDA may be referred to as a non-display region of the display device DM.

As shown in FIG. 1, the active region DD-DA may have a substantially quadrangular shape. The “substantially quadrangular shape” may include not only a quadrangular shape having mathematical meaning but also a quadrangular shape in which not a vertex but a curved boundary is defined in a vertex region (a corner region).

The bezel region DD-NDA may surround the active region DD-DA. However, the embodiment of the disclosure is not limited thereto, and the bezel region DD-NDA may be modified in shape. For example, the bezel region DD-NDA may be disposed on only a side of the active region DD-DA.

FIG. 2 is a schematic cross-sectional view of an electronic device DD according to an embodiment.

The electronic device DD may include a display device DM, and a window WM disposed on the display device DM. The display device DM and the window WM may be bonded through an adhesive layer PSA. However, the embodiment of the disclosure is not limited thereto, and the adhesive layer PSA may not be provided in an embodiment. The window WM may be formed through a coating method, and the window WM may be directly disposed on the display device DM.

The display device DM may include a display panel 100, an input sensor 200, and a light control member 300. The display panel 100 may include a base layer BS, a circuit layer DP-CL, a display layer DP-ED, and an encapsulation layer TFE.

The display panel 100 according to an embodiment may be a light emitting display panel, and is not particularly limited thereto. For example, the display panel 100 may be an organic light emitting display panel, an inorganic light emitting display panel, or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include quantum dots, quantum rods, and the like. Hereinafter, the display panel 100 is described as an organic light emitting display panel. The display panel 100 will be described in more detail later.

The input sensor 200 may be disposed on the display panel 100. The input sensor 200 may detect user inputs using, for example, an electromagnetic induction method and or a capacitive method. The input sensor 200 may be directly disposed on the display panel 100. “Being directly disposed” as described herein may indicate that an intervening third component is not disposed between the input sensor 200 and the display panel 100. For example, a separate adhesive layer may not be disposed between the input sensor 200 and the display panel 100. The display panel 100 and the input sensor 200 may be formed through a continuous process.

The light control member 300 may be a reflection reduction layer that reduces external light reflectance caused by light incident from outside the electronic device DD. However, the embodiment of the disclosure is not limited thereto, and the light control member 300 may include various components of the light control layer to improve the display quality of the electronic device DD. For example, the light control member 300 according to an embodiment may include a polarizing layer, a phase retarder, a destructive interference structure, or multiple color filters. Meanwhile, in the electronic device DD according to an embodiment, the light control member 300 may not be provided.

The window WM according to an embodiment may include a base substrate and a light blocking pattern. The base substrate may include a glass substrate and/or a synthetic resin film. The light blocking pattern may partially overlap the base substrate. The light blocking pattern may substantially correspond to the bezel region DD-NDA (see FIG. 1) of the electronic device DD. A region where the light blocking pattern is not disposed may correspond to the active region DD-DA (see FIG. 1) of the display device DM. Meanwhile, herein, the phrase “a region/portion corresponds to another region/portion” indicates that “the regions/portions overlap each other”, and is not limited to having the same surface area and/or having the same shape. Herein, the phrase “a region/portion and a region/portion overlap” includes a case in which a region/portion and a region/portion that are indicated as overlapping in a plan view at least partially overlap in a plan view.

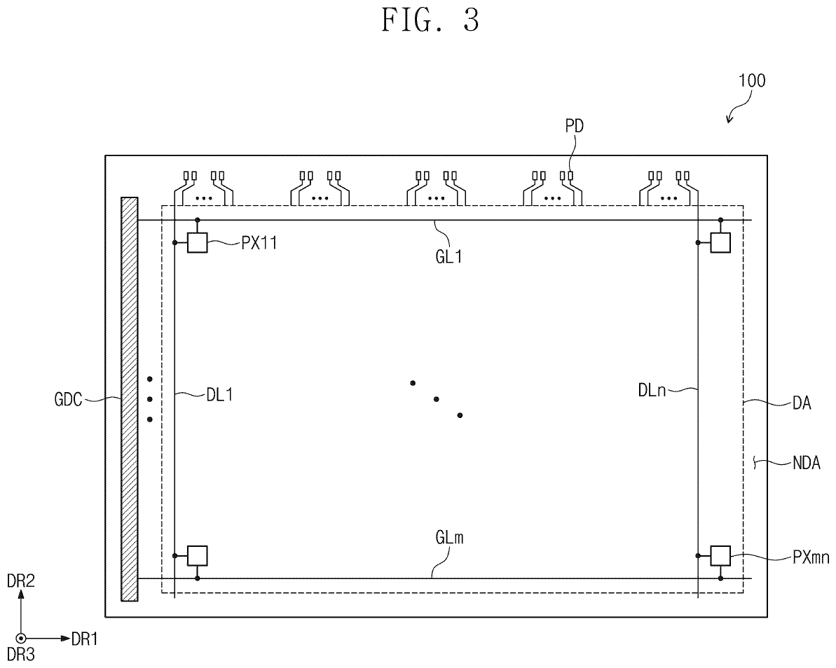

FIG. 3 is a schematic plan view of a display panel according to an embodiment. In FIG. 3, a planar arrangement relationship of signal lines GL1 to GLm and DL1 to DLn and pixels PX11 to PXmn among the components of the display panel 100 is shown. The signal lines GL1 to GLm and DL1 to DLn may include multiple gate lines GL1 to GLm and multiple data lines DL1 to DLn.

The display panel 100 may include a display region DA and a non-display region NDA. The non-display region NDA may be disposed on at least a side of the display region DA. The pixels PX11 to PXmn may be disposed in the display region DA, and a portion or some regions of the signal lines GL1 to GLm and DL1 to DLn may be disposed in the non-display region NDA.

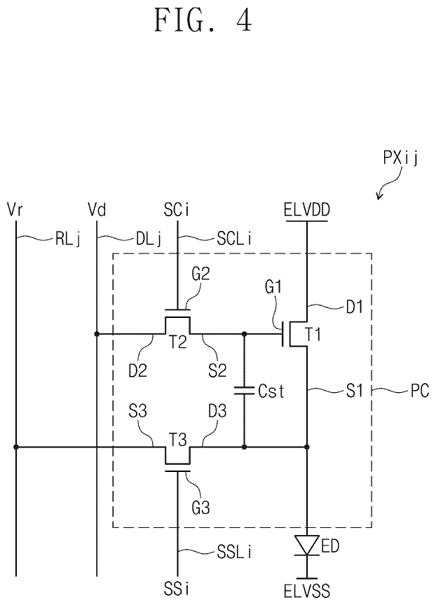

Each of the pixels PX11 to PXmn may be electrically connected to a corresponding gate line among multiple gate lines GL1 to GLm and a corresponding data line among multiple data lines DL1 to DLn. Each of the pixels PX11 to PXmn may include a pixel driving circuit and a light emitting element. More types of signal lines may be provided in the display panel 100 according to configuration of the pixel driving circuit of the pixels PX11 to PXmn. For example, each of the gate lines GL1 to GLm may include a corresponding scan line SCLi (see FIG. 4) and a corresponding sensing line SSLi (see FIG. 4).

The gate driving circuit GDC may be integrated into the display panel 100 through an oxide semiconductor gate driver circuit (OSG) process. The gate driving circuit GDC may be formed directly on the base layer BS (see FIG. 2) and included in the display panel DP. For example, the gate driving circuit GDC of an embodiment is different from a gate driving circuit that is mounted on a circuit board as a separate member and then connected to the circuit layer DP-CL (see FIG. 2), and the gate driving circuit GDC may be formed by directly being patterned on the base layer BS (see FIG. 2). The gate driving circuit GDC connected to the gate lines GL1 to GLm may be disposed in the non-display region NDA.

Referring to FIG. 3, the gate driving circuit GDC may be disposed in the non-display region NDA placed at a side of the display region DA in the first direction DR1. Pads PD electrically connected to an end of multiple data lines DL1 to DLn may be disposed in the non-display region NDA placed at a side of the display region DA in the second direction DR2. However, it is an example and the embodiment of the disclosure is not limited thereto, and the arrangement positions of the gate driving circuit GDC and the pads PD may vary in other embodiments.

The gate driving circuit GDC may include multiple transistors formed through the same process as at least one of pixel transistors included in a pixel circuit of pixels PXij described below. At least one of multiple transistors included in the gate driving circuit GDC may include a semiconductor pattern including a metal oxide including at least one of indium, gallium, zinc, tin, or titanium.

FIG. 4 is a schematic diagram of an equivalent circuit of pixels according to an embodiment. FIG. 4 shows a pixel PXij connected to an i-th scan line SCLi, an i-th sensing line SSLi, a j-th data line DLj, and a j-th reference line RLj as an example. The pixel PXij may include a pixel circuit PC and a light emitting element ED connected to the pixel circuit PC. The pixel circuit PC may include multiple pixel transistors T1, T2, and T3 and at least one capacitor Cst. At least one of multiple pixel transistors T1, T2, and T3 may include a semiconductor pattern including a metal oxide including at least one of indium, gallium, zinc, tin, or titanium. For example, t multiple pixel transistors T1, T2, and T3 may all include a semiconductor pattern including a metal oxide.

Hereinafter, multiple pixel transistors T1, T2, and T3 will be described as N-type transistors, but at least one transistor may be provided as a P-type transistor.

In FIG. 4, a pixel circuit PC including a first pixel transistor T1, a second pixel transistor T2, a third pixel transistor T3, and a pixel capacitor Cst is shown as an example, but the components of the pixel circuit PC are not limited thereto.

The first pixel transistor T1 may be a driving transistor, and the second pixel transistor T2 may be a switching transistor. The third pixel transistor T3 may be a sensing transistor. The pixel circuit PC may further include additional transistors in addition to the first to third pixel transistors T1, T2, and T3, or may further include additional capacitors in addition to the pixel capacitor Cst.

The light emitting element ED may be an organic light emitting element or an inorganic light emitting element, which includes an anode (a first electrode) and a cathode (a second electrode). The anode of the light emitting element ED may receive a first voltage ELVDD through the first pixel transistor T1, and the cathode of the light emitting element ED may receive a second voltage ELVSS. The light emitting element ED may receive the first voltage ELVDD and the second voltage ELVSS to emit light.

The first pixel transistor T1 may include a drain D1 receiving the first voltage ELVDD, a source S1 connected to the anode of the light emitting element ED, and a gate G1 connected to the pixel capacitor Cst. The first pixel transistor T1 may control a driving current flowing through the light emitting element ED from the first voltage ELVDD in response to voltage values stored in the pixel capacitor Cst.

The second pixel transistor T2 may include a drain D2 connected to a j-th data line DLj, a source S2 connected to the pixel capacitor Cst, and a gate G2 receiving an i-th first scan signal SCi. The j-th data line DLj may receive a data voltage Vd. The second pixel transistor T2 may provide the data voltage Vd to the first pixel transistor T1 in response to the i-th first scan signal SCi.

The third pixel transistor T3 may include a source S3 connected to a j-th reference line RLj, a drain D3 connected to the anode of the light emitting element ED, and a gate G3 receiving an i-th second scan signal SSi. The j-th reference line RLj may receive a reference voltage Vr. The third pixel transistor T3 may initialize the pixel capacitor Cst and the anode of the light emitting element ED.

The pixel capacitor Cst may store a voltage corresponding to a difference between a voltage received from the second pixel transistor T2 and the first voltage ELVDD. The pixel capacitor Cst may be connected to the gate G1 of the first pixel transistor T1 and the anode of the light emitting element ED.

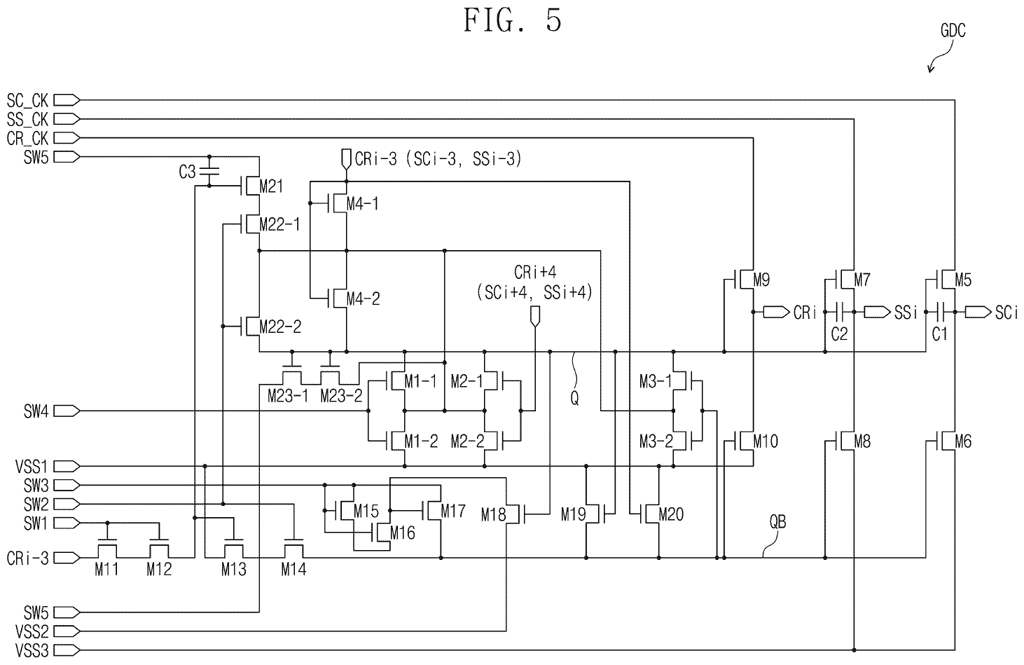

FIG. 5 is a schematic diagram of an equivalent circuit of a gate driving circuit GDC according to an embodiment. In FIG. 5, a portion of the gate driving circuit GDC that outputs an i-th first scan signal SCi and an i-th second scan signal SSi is shown. For example, i is a natural number of 1 to m.

The gate driving circuit GDC may include multiple stages. The gate driving circuit GDC may include multiple stages electrically connected to each of the gate lines GL1 to GLm. T multiple stages may be arranged and positioned in the second direction DR2.

Multiple stages included in the gate driving circuit GDC may each provide driving signals to pixels in a corresponding row. Multiple stages may each include multiple transistors. Two or more transistors selected from among multiple transistors included in each stage may be disposed to be vertically stacked with semiconductor patterns overlapping. The disposing of the transistors to overlap in a plan view may minimize an area of the non-display region NDA, (see FIG. 3).

Some of multiple transistors included in each stage of the gate driving circuit GDC are disposed to overlap in a plan view, and thus each of the stages may have a reduced width in the second direction DR2, resulting in reduced arrangement interval of the pixels PX11 to PXmn. Therefore, the disposing of some of multiple transistors included in the gate driving circuit GDC to overlap may enable a high-resolution display device.

FIG. 5 may be a schematic diagram of an equivalent circuit of one stage among multiple stages. The gate driving circuit GDC may include all circuit components (e.g., m or more stages) for outputting first scan signals SCi (i is an integer of 1 to m) and second scan signals SSi (i is an integer of 1 to m).

Meanwhile, the circuit shown in FIG. 5 is merely presented as an example of the gate driving circuit GDC, and the circuit configuration of the gate driving circuit GDC may be variously changed.

Referring to FIG. 5, the gate driving circuit GDC may receive clock signals SC_CK, SS_CK, and CR_CK, switching signals SW1 to SW5, carry signals CRi−3 and CRi+4, a first low voltage VSS1, a second low voltage VSS2, and a third low voltage VSS3, and output a first scan signal SCi, a second scan signal SSi, and a carry signal CRi. The carry signals CRi+3 and CRi+4 may be signals generated within the gate driving circuit GDC. For example, the i−3th carry signal CRi−3 may be a signal related to an i−3th first scan signal SCi−3 and an i−3th second scan signal SSi−3, and an i+4th carry signal CRi+4 may be a signal related to an i+4th first scan signal SCi+4 and an i+4th second scan signal SSi+4.

The gate driving circuit GDC may include transistors M1-1, M1-2, M2-1, M2-2, M3-1, M3-2, M4-1, M4-2, M5, M6, M7, M8, M9, M10, M11, M12, M13, M14, M15, M16, M17, M18, M19, M20, M21, M22-1, M22-2, M23-1, and M23-2, and capacitors C1, C2, and C3.

The switching signals SW1 and SW4 may transition to a high level at the beginning of a frame, and then stay at a low level for the remaining duration of the frame. Each of the switching signals SW1 and SW4 may be a signal indicating the beginning of a frame. A frame may include an active period and a blank period.

The switching signal SW2 may stay at a low level (e.g., about −9 V) during the active period and transitions to a high level (e.g., about 25 V) at the beginning of the blank period. The switching signal SW2 may be a signal indicating the beginning of the blank period.

The switching signal SW3 may stay at a high level (e.g., about 25 V) or a low level (e.g., about −9 V) during one frame.

The switching signal SW5 may be a signal that stays at a high level (e.g., about 25 V).

The gate driving circuit GDC shown in FIG. 5 may operate as follows.

In case that the switching signal SW4 transitions to a high level at the beginning of one frame, the transistors M1-1 and M1-2 may be turned on, and a first node Q may be initialized to the first low voltage VSS1.

The transistors M15, M16, and M17 may be turned on while the switching signal SW3 is at a high level (e.g., about 25 V), and thus a second node QB may be set to a high level corresponding to the switching signal SW3.

In case that the carry signal CRi−3 transitions to a high level, the transistors M4-1 and M4-2 may be turned on, and the first node Q may transition to a high level. In case that the first node Q transitions to a high level and the clock signals SC_CK, SS_CK, and CR_CK are at a high level, the transistors M5, M7, and M9 may be turned on, and thus the first scan signal SCi, the second scan signal SSi, and the carry signal CRi may each transition to a high level. Meanwhile, in case that the carry signal CRi−3 transitions to a high level, the transistor M20 is turned on, and thus the second node QB may be discharged to the first low voltage VSS1.

The transistors M5, M7, and M9 may be transistors that control the output of the scan signal SCi or SSi provided to the light emitting elements ED (see FIG. 4) or control the carry signal CRi provided to the next stage, and may be referred to as switching transistors M5, M7, and M9. Channel widths of the switching transistors M5, M7, and M9 may be greater than channel widths of the other transistors M1-1, M1-2, M2-1, M2-2, M3-1, M3-2, M4-1, M4-2, M6, M8, M10, M11, M12, M13, M14, M15, M16, M17, M18, M19, M20, M21, M22-1, M22-2, M23-1, and M23-2. The transistor M1-1 and M1-2 may be electrically connected in series, the transistor M2-1 and M2-2 may be electrically connected in series, the transistor M3-1 and M3-2 may be electrically connected in series, the transistor M4-1 and M4-2 may be electrically connected in series, the transistor M22-1 and M22-2 may be electrically connected in series, and the transistor M23-1 and M23-2 may be electrically connected in series.

Meanwhile, the transistor M19 may be turned on in case that the first node Q is at a high level, the second node QB may stay at the first low voltage VSS1, i.e., a low level. Therefore, the transistors M6, M8, and M10 may stay in a turned-off state.

In case that each of the clock signals SC_CK, SS_CK, and CR_CK turn from a high level to a low level, each of the first scan signal SCi, the second scan signal SSi, and the carry signal CRi may transition from a high level to a low level.

In case that the carry signal CRi+4 transitions to a high level, the transistors M2-1 and M2-2 may be turned on, and the first node Q may be discharged to the first low voltage VSS1.

In case that the first node Q is at the first low voltage VSS1 and the carry signal CRi−3 is at a low level, each of the transistors M19 and M20 may be turned off, and thus the second node QB may stay at a high level corresponding to the third switching signal SW3. In case that the second node QB is at a high level, the transistors M6, M8, and M10 may be turned on, and thus the first scan signal SCi and the second scan signal SSi may stay at a voltage level of the third low voltage VSS3, and the carry signal CRi may stay at a voltage level of the first low voltage VSS1. For example, in the blank period within one frame, the first scan signal SCi and the second scan signal SSi may stay at the third low voltage VSS3, and the carry signal CRi may stay at the first low voltage VSS1.

At least one of the transistors included in the gate driving circuit GDC may include an oxide semiconductor pattern. The oxide semiconductor pattern may include a metal oxide including at least one of indium, gallium, zinc, tin, or titanium.

Multiple transistors included in the gate driving circuit GDC may include a lower transistor and an upper transistor with the semiconductor patterns disposed to overlap in a plan view, and may include a conductive pattern disposed between the lower transistor and the upper transistor. The conductive pattern may be electrically connected to a voltage line to which a predetermined voltage is applied. A DC voltage may be applied to the conductive pattern through the voltage line.

For example, any one of the switching transistors M5, M7, and M9 that control the output of signals provided to light emitting elements may be disposed as a lower transistor, and one of the others may be disposed as an upper transistor overlapping the lower transistor. A conductive pattern may be disposed between the lower transistor and the upper transistor.

The display device of an embodiment may have two or more transistors selected from multiple transistors included in the gate driving circuit GDC with semiconductor patterns disposed to overlap and may include a conductive pattern disposed between the overlapping transistors, and may thus reduce an arrangement area of the gate driving circuit GDC, thereby exhibiting a reduced area of the non-display region NDA.

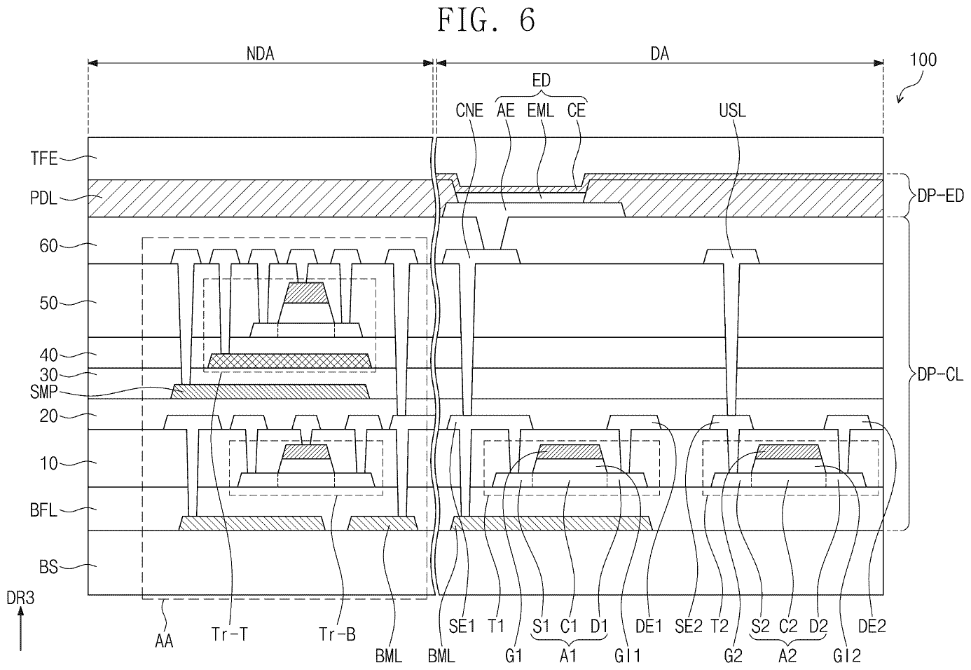

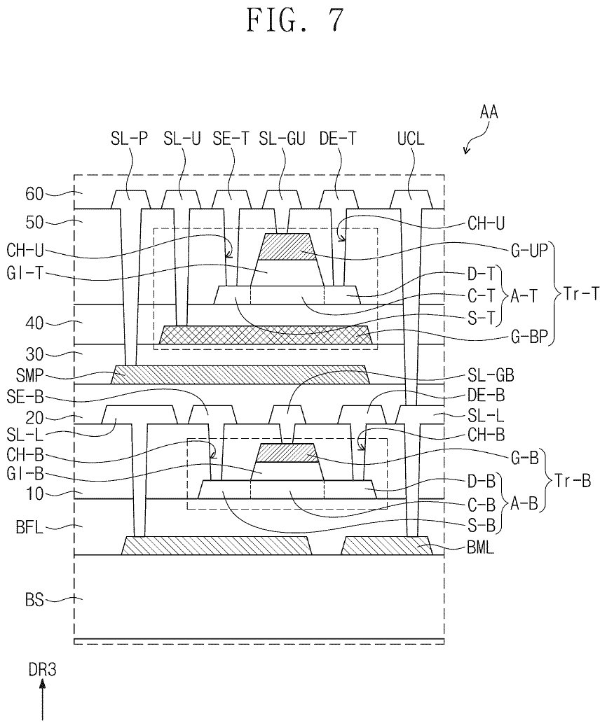

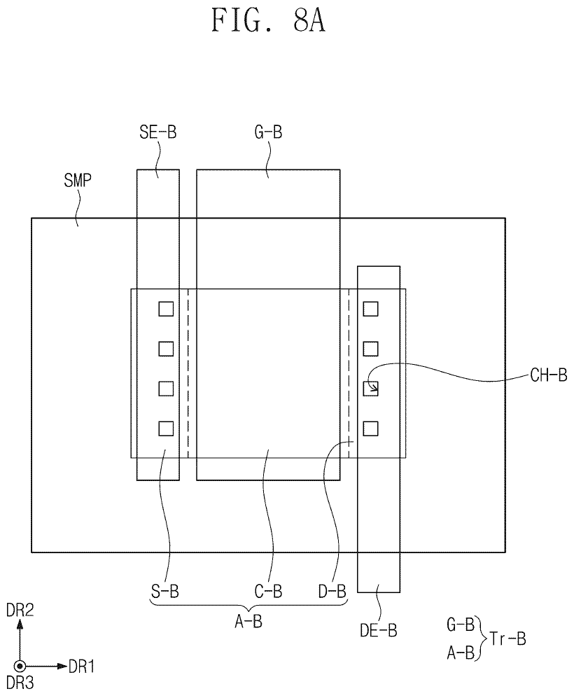

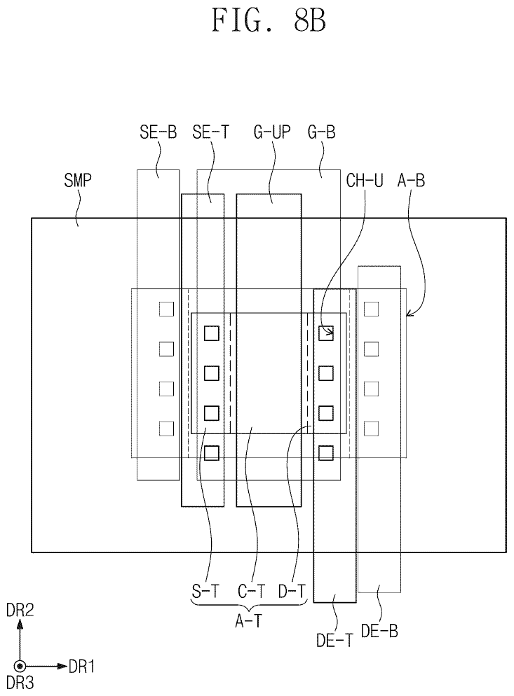

FIG. 6 is a schematic cross-sectional view of a display panel according to an embodiment. FIG. 6 shows components of a display panel in a portion of a display region and a portion of a non-display region. FIG. 7 is a view enlarging region AA of FIG. 6. FIGS. 8A and 8B are schematic plan views each showing a portion of a display panel. FIGS. 8A and 8B may be schematic plan views showing some regions of a portion corresponding to region AA shown in FIG. 7.

The display panel 100 may include a base layer BS, a circuit layer DP-CL disposed on the base layer, and a display layer DP-ED disposed on the circuit layer DP-CL. The circuit layer DP-CL may include multiple transistors, and the display layer DP-ED may include a light emitting element ED.

The base layer BS may provide a base surface on which the circuit layer DP-CL is disposed. The base layer BS may include a glass substrate, a metal substrate, a polymer substrate, or an organic/inorganic composite material substrate.

The base layer BS may include at least one synthetic resin layer. The synthetic resin layer included in the base layer BS may include at least any one of an acryl-based resin, a methacrylate-based resin, polyisoprene, a vinyl-based resin, an epoxy-based resin, a urethane-based resin, a cellulose-based resin, a siloxane-based resin, a polyamide-based resin, a polyimide-based resin, or a perylene-based resin.

The base layer BS may be a flexible substrate. In case that the base layer BS is a flexible substrate, the base layer BS may be bendable, foldable, or rollable.

The circuit layer DP-CL may be disposed on the base layer BS. The circuit layer DP-CL may include multiple insulating layers, multiple semiconductor patterns, multiple conductive patterns, multiple electrodes, signal lines, and the like. The circuit layer DP-CL will be described in more detail later.

The display layer DP-ED may be disposed on the circuit layer DP-CL. The display layer DP-ED may include a pixel defining film PDL and a light emitting element ED. For example, the light emitting element ED may include organic light emitting materials, inorganic light emitting materials, organic-inorganic light emitting materials, quantum dots, quantum rods, micro LEDs, or nano LEDs.

The light emitting element ED may include a first electrode AE, a second electrode CE, and an emission layer EML. The first electrode AE of the light emitting element ED may be an anode, and the second electrode CE may be a cathode.

The first electrode AE of the light emitting element ED and the pixel defining film PDL may be disposed on an upper insulating layer 60. The first electrode AE may be electrically connected to a connection electrode CNE at least through a contact hole passing through the upper insulating layer 60. The first electrode AE may be electrically connected to the connection electrode CNE, and thus the first electrode AE may be electrically connected to each of a first source S1 of the first pixel transistor T1 and a lower shielding pattern BML through the connection electrode CNE and a source electrode SE2. For example, the first electrode AE of the light emitting element ED may be electrically connected to each of a semiconductor pattern A1 of the first pixel transistor T1 and the lower shielding pattern BML.

A light emitting opening exposing a portion of the first electrode AE may be defined in the pixel defining film PDL. A portion of the first electrode AE exposed through the light emitting opening may correspond to a light emitting region.

The pixel defining film PDL may include a polymer resin and may further include an inorganic material included in the polymer resin. The pixel defining film PDL of an embodiment may have a predetermined color. For example, the pixel defining film PDL may include a base resin and a black pigment and/or a black dye mixed with the base resin. However, the embodiment of the pixel defining film PDL is not limited thereto.

The second electrode CE may be disposed to oppose the first electrode AE. The second electrode CE may be disposed (or commonly disposed) in pixels PX11 to PXmn (see FIG. 3) disposed in the display region DA. For example, the second electrode CE may be a common electrode commonly provided to multiple pixels PX11 to PXmn (see FIG. 3).

The emission layer EML may be disposed between the first electrode AE and the second electrode CE. The emission layer EML may include an organic material and/or an inorganic material. The emission layer EML may be disposed in a region corresponding to the light emitting opening defined in the pixel defining film PDL. For example, the emission layer EML may generate any one among red light, green light, and blue light. However, the embodiment of the disclosure is not limited thereto, and the emission layer EML may be disposed (or commonly disposed) in pixels and may generate blue light or white light. In FIG. 6, the light emitting element ED may be shown to include one emission layer EML as an example, but the light emitting element ED may be a tandem-type light emitting element including multiple light emitting stacks.

The light emitting element ED may further include at least one functional layer provided between the first electrode AE and the emission layer EML, and between the emission layer EML and the second electrode CE. The light emitting element ED may further include, for example, a hole control layer provided between the first electrode AE and the emission layer EML, and an electron control layer provided between the second electrode CE and the emission layer EML. Each of the hole control layer and the electron control layer may be disposed (or commonly disposed) in pixels. The hole control layer may include at least one of a hole injection layer, a hole transport layer, or an electron blocking layer. The electron control layer may include at least one of an electron injection layer, an electron transport layer, or a hole blocking layer.

The encapsulation layer TFE may be disposed on the display layer DP-ED. The encapsulation layer TFE may serve to protect the display layer DP-ED, which is a light emitting element, from moisture, oxygen, and foreign substances such as dust particles. The encapsulation layer TFE may include at least one inorganic encapsulation layer. The encapsulation layer TFE may include a stack structure of a first inorganic encapsulation layer/an organic encapsulation layer/a second inorganic encapsulation layer.

Through coating or deposition, an insulating layer, a semiconductor layer, a conductive layer, and the like are provided on the base layer BS, and then patterned through multiple photolithography processes to form multiple insulating layers and insulating patterns, multiple semiconductor patterns, multiple conductive patterns, multiple electrodes, and signal lines of the circuit layer DP-CL. Based on the stacking order of patterns included in the circuit layer DP-CL, the deposition, photo, and etching processes may be sequentially repeated.

The circuit layer DP-CL may include multiple pixel transistors constituting the pixel circuit PC (see FIG. 4) of the pixels PX11 to PXmn (see FIG. 3), and multiple transistors constituting the gate driving circuit GDC (see FIG. 3).

Meanwhile, the cross-sectional structure of the circuit layer DP-CL shown in FIG. 6 and the like is an example, and may vary based on the manufacturing process of the circuit layer DP-CL, the configuration of the pixel circuit, or the configuration of the gate driving circuit.

The circuit layer DP-CL may include a buffer layer BFL, first to fifth insulating layers 10, 20, 30, 40, and 50, and an upper insulating layer 60 as an insulating layer. The circuit layer DP-CL may include a lower shielding pattern BML and a conductive pattern SMP. The circuit layer DP-CL may include multiple transistors T1, T2, Tr-B, and Tr-T, electrode patterns CNE, SE1, SE2, DE1, DE2, SE-T, SE-B, DE-T, DE-B, UCL, and USL, and signal lines SL-P, SL-GU, SL-GB, SL-U, and SL-L. The electrode patterns CNE, SE1, SE2, DE1, DE2, SE-T, SE-B, DE-T, DE-B, UCL, and USL may be electrically connected to the transistors T1, T2, Tr-B, and Tr-T, the lower shielding pattern BML, or the conductive pattern SMP. The signal lines SL-P, SL-GU, SL-GB, SL-U, and SL-L may be electrically connected to the lower shielding pattern BML, the conductive pattern SMP, or the transistors Tr-B and Tr-T.

The lower shielding pattern BML may be disposed on the base layer BS. The lower shielding pattern BML may be formed of a metal material. The lower shielding pattern BML may be disposed to overlap a transistor and the like to protect a semiconductor pattern of the transistor in the third direction DR3. The lower shielding pattern BML may be disposed below a transistor to block an electric potential from affecting the transistor, or to block external light from reaching the transistor.

Meanwhile, the lower shielding pattern BML may be electrically connected to an electrode or a line to receive a predetermined constant voltage. The lower shielding pattern BML may be a floating pattern, isolated from other electrodes or lines.

The buffer layer BFL may be disposed on the base layer BS. The buffer layer BFL may improve the bonding strength between the base layer BS and the semiconductor patterns A1, A2, and A-B and/or the lower shielding pattern BML. The buffer layer BFL may cover the lower shielding pattern BML. The buffer layer BFL may include at least one inorganic layer, for example, the buffer layer BFL may include at least one of aluminum oxide, titanium oxide, silicon oxide, silicon nitride, silicon oxynitride, zirconium oxide, or hafnium oxide.

The first to fifth insulating layers 10, 20, 30, 40, and 50 may be disposed on the buffer layer BFL. The first to fifth insulating layers 10, 20, 30, 40, and 50 may be disposed to be sequentially stacked in the third direction DR3. The upper insulating layer 60 may be disposed on the fifth insulating layer 50. However, the embodiment of the disclosure is not limited thereto, and the number and stack structure of the insulating layers included in the circuit layer DP-CL are not limited to what is shown in an embodiment.

The first insulating layer 10 may be disposed on the buffer layer BFL. The first insulating layer 10 may be an inorganic layer. Contact holes exposing sources S1, S2, and S-B and drains D1, D2, and D-B may be defined in the first insulating layer 10. In addition, contact holes in which connection electrodes and the like connected to the lower shielding pattern BML are disposed may be defined in the first insulating layer 10.

The second insulating layer 20 may be disposed on the first insulating layer 10. The second insulating layer 20 may be an inorganic layer. Referring to FIG. 6 and the like, the second insulating layer 20 may cover electrode patterns or lines disposed on the first insulating layer 10. An upper surface of the second insulating layer 20 may be a flat surface.

The third insulating layer 30 may be disposed on the second insulating layer 20. The third insulating layer 30 may may cover the conductive pattern SMP disposed on the second insulating layer 20. The third insulating layer 30 may be an inorganic layer. An upper surface of the third insulating layer 30 may be a flat surface. At least one of the upper surface of the second insulating layer 20 or the upper surface of the third insulating layer 30 may be a flat surface.

The pixel transistors T1 and T2 and the first transistor Tr-B may be covered through the second insulating layer 20 and the third insulating layer 30. The second insulating layer 20 and the third insulating layer 30 may each be layers containing silicon nitride. The second insulating layer 20 and the third insulating layer 30 may each have a stack structure in which multiple layers are stacked. In case that the second insulating layer 20 or the third insulating layer 30 has a structure including multiple layers, at least one of multiple layers may be a planarization layer.

The fourth insulating layer 40 may be disposed on the third insulating layer 30. The second transistor Tr-T may be disposed on the third insulating layer 30, the fourth insulating layer 40 may cover a lower electrode G-BP disposed on the third insulating layer 30, and a second semiconductor pattern A-T and an upper electrode G-UP of the second transistor Tr-T may be disposed on the fourth insulating layer 40. The fourth insulating layer 40 may be an inorganic layer. However, the embodiment of the disclosure is not limited thereto.

The fifth insulating layer 50 may be disposed on the fourth insulating layer 40. The fifth insulating layer 50 may cover the second transistor Tr-T. The fifth insulating layer 50 may be an inorganic layer.

The upper insulating layer 60 may be disposed on the fifth insulating layer 50. The upper insulating layer 60 may be an organic layer. Referring to FIG. 6, the upper insulating layer 60 may cover electrode patterns or lines disposed on the fifth insulating layer 50. A contact hole may be defined in the upper insulating layer 60, and the light emitting element ED and pixel transistors may be electrically connected through the contact hole of the upper insulating layer 60.

A contact hole may be defined in the buffer layer BFL or the insulating layers 10, 20, 30, 40, and 50. The contact hole may be formed as passing through some of the insulating layers among the stacked insulating layers, or may be defined only in some regions without passing through one insulating layer. Through the contact hole, a lower shielding pattern and electrodes may be electrically connected, a semiconductor pattern and an electrode pattern or a semiconductor pattern and a line may be electrically connected, a light emitting element and a transistor may be electrically connected, or a line and a conductive pattern may be electrically connected.

For example, the connection electrode CNE may be electrically connected to the source electrode SE1 connected to the source S1 of the first pixel transistor through a contact hole formed through the second to fifth insulating layers 20, 30, 40, and 50. The source electrode SE1 of the first pixel transistor may be electrically connected to the source S1 through a contact hole defined in the first insulating layer 10, and may also be electrically connected to the lower shielding pattern BML through a contact hole defined in the first insulating layer 10 and the buffer layer BFL.

Referring to FIGS. 6 and 7, multiple transistors Tr-T, Tr-B, T1, and T2 may be disposed on the buffer layer BFL. The first pixel transistor T1 and the second pixel transistor T2 may be disposed in the display region DA, and the first transistor Tr-B and the second transistor Tr-T may be disposed in the non-display region NDA.

Multiple transistors Tr-T, Tr-B, T1, and T2 may each include a semiconductor pattern. Each of the semiconductor patterns may include a source region, a channel region, and a drain region. In the semiconductor pattern, the source region, the channel region, and the drain region may be regions differentiated by doping concentration or conductivity.

At least one of multiple transistors Tr-T, Tr-B, T1, and T2 may include an oxide semiconductor. For example, the semiconductor pattern of the transistors Tr-T, Tr-B, T1, and T2 may include an oxide semiconductor.

The inclusion of an oxide semiconductor material may increase electron mobility in the transistors Tr-T, Tr-B, T1, and T2, and reduce leakage current. Meanwhile, oxide semiconductors included in each of multiple transistors Tr-T, Tr-B, T1, and T2 may all be the same. However, the embodiment of the disclosure is not limited thereto, and at least any one of the oxide semiconductors included in the semiconductor pattern of each of multiple transistors Tr-T, Tr-B, T1, and T2 may be a different material from the other materials.

The oxide semiconductors may also be referred to as metal oxide semiconductors. The oxide semiconductor materials may be crystalline or amorphous oxides. For example, the semiconductor pattern may include a metal oxide such as zinc (Zn), indium (In), gallium (Ga), tin (Sn), and titanium (Ti), or a mixture of metals such as zinc (Zn), indium (In), gallium (Ga), tin (Sn), and titanium (Ti) and an oxide thereof. The semiconductor pattern may include a transparent conductive oxide (TCO) such as indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), and zinc-tin oxide (ZTO), as an oxide semiconductor material.

The oxide semiconductor may include multiple regions divided according to whether metal oxides are reduced. A region in which the metal oxides are reduced (hereinafter, reduction region) has greater conductivity than a region in which the metal oxides are not reduced (hereinafter, non-reduction region). The reduction region substantially may serve as a source/drain of a transistor, or a signal line. The non-reduction region substantially corresponds to a channel region (or semiconductor region, active region) of a transistor. For example, a portion of the semiconductor pattern may be a channel region of a transistor, another portion may be a source/drain region of a transistor, and the other portion may be a signal transmission region.

Meanwhile, herein, the semiconductor pattern may be referred to as an active layer. The non-reduction region may be referred to as a channel region, and the reduction region may be referred to as a source region or a drain region based on the applied voltage.

The display panel 100 according to an embodiment may include multiple transistors disposed in the non-display region NDA. The display panel 100 may include a first transistor Tr-B and a second transistor Tr-T disposed in the non-display region NDA and overlapping in the third direction DR3. Referring to FIGS. 6 to 8B, the overlapping of the transistors Tr-B and Tr-T corresponds to the overlapping of at least a portion of the semiconductor patterns A-B and A-T of the transistors in the third direction DR3.

The first transistor Tr-B may be disposed on the buffer layer BFL, and the second transistor Tr-T may be disposed on an upper portion of the first transistor Tr-B. The first transistor Tr-B may be referred to as a lower transistor, and the second transistor Tr-T may be referred to as an upper transistor. The conductive pattern SMP may be disposed between the first transistor Tr-B and the second transistor Tr-T. Meanwhile, FIG. 8A shows, as an example, a plane in which the conductive pattern SMP is disposed on the first transistor Tr-B and the first transistor Tr-B, and FIG. 8B shows, as an example, a plane in which the second transistor Tr-T is disposed on a stack structure of the first transistor Tr-B and the conductive pattern SMP in FIG. 8A. In FIGS. 8A and 8B, the stack structure is shown without a portion thereof, and the overlapping relationship between the semiconductor pattern of the first transistor Tr-B, the conductive pattern SMP, and the semiconductor pattern of the second transistor Tr-T is mainly shown.

Referring to FIGS. 6 to 8B, the first transistor Tr-B may include a lower semiconductor pattern (or first semiconductor pattern, A-B) and a first upper electrode G-B. The first upper electrode G-B may be referred to as a first gate electrode. The lower semiconductor pattern A-B may be divided into a first source (or first source region, S-B), a first channel (or first channel region, C-B), and a first drain (or first drain region, D-B). A lower insulating pattern GI-B may be disposed between the lower semiconductor pattern A-B and the first upper electrode G-B. The first upper electrode G-B may be disposed on the lower insulating pattern GI-B and may be spaced apart from the lower semiconductor pattern A-B in the third direction DR3. The first upper electrode G-B may overlap the first channel C-B in the third direction DR3. For example, a width of the first channel C-B may be determined to correspond to the first upper electrode G-B.

The second transistor Tr-T may include an upper semiconductor pattern (or second semiconductor pattern, A-T), a second upper electrode G-UP, and a lower electrode G-BP. The second upper electrode G-UP may be referred to as a second upper gate electrode, and the lower electrode G-BP may be referred to as a second lower gate electrode. The second upper electrode G-UP and the lower electrode G-BP may each be electrically connected to the upper semiconductor pattern A-T.

The upper semiconductor pattern A-T may be divided into a second source (or second source region, S-T), a second channel (or second channel region, C-T), and a second drain (or second drain region, D-T). An upper insulating pattern GI-T may be disposed between the upper semiconductor pattern A-T and the second upper electrode G-UP. The second upper electrode G-UP may be disposed on the upper insulating pattern GI-T and may be spaced apart from the upper semiconductor pattern A-T in the third direction DR3. The second upper electrode G-UP may overlap the second channel C-T in the third direction DR3. For example, a width of the second channel C-T may be determined to correspond to the second upper electrode G-UP. The lower electrode G-BP may be disposed on a lower side of the upper semiconductor pattern A-T and may be spaced apart with the fourth insulating layer 40 therebetween in the third direction DR3.

At least one of the first transistor Tr-B or the second transistor Tr-T may include an oxide semiconductor. For example, the lower semiconductor pattern A-B of the first transistor Tr-B and the upper semiconductor pattern A-T of the second transistor Tr-T may include oxide semiconductors.

The lower semiconductor pattern A-B and the upper semiconductor pattern A-T may include oxide semiconductors having the same or different compositions or ratios. At least one of the oxide semiconductors included in the lower semiconductor pattern A-B and the upper semiconductor pattern A-T may have a mobility of about 20 cm²/Vs or greater.

For example, the lower semiconductor pattern A-B and the upper semiconductor pattern A-T may each independently be an oxide semiconductor including a metal oxide including indium (In), gallium (Ga), and zinc (Zn).

The lower semiconductor pattern A-B may include IGZO, and the upper semiconductor pattern A-T may include a material having a greater mobility than the IGZO of the lower semiconductor pattern A-B. Conversely, the upper semiconductor pattern A-T may include IGZO and the lower semiconductor pattern A-B may include a material having a greater mobility than the IGZO of the upper semiconductor pattern A-T.

The content of indium in the metal oxide included in the lower semiconductor pattern A-B and the upper semiconductor pattern A-T may be at least twice the content of gallium.

Referring to FIGS. 7 to 8B, the lower shielding pattern BML may be disposed below the lower semiconductor pattern A-B of the first transistor Tr-B. The lower shielding pattern BML may be electrically connected to a lower line SL-L through a contact hole defined in the buffer layer BFL and the first insulating layer 10. For example, the lower line SL-L may be a line to which a constant voltage is applied.

The first source S-B, the first drain D-B, and the first upper electrode G-B of the first transistor Tr-B may be electrically connected to electrodes or signal lines through a first contact hole CH-B defined in the first insulating layer 10. The first source S-B may be electrically connected to the first source electrode SE-B, the first drain D-B may be electrically connected to the first drain electrode DE-B, and the first upper electrode G-B may be electrically connected to the first gate line SL-GB. The lower line SL-L, the first source electrode SE-B, the first drain electrode DE-B, and the first gate line SL-GB may be covered through the second insulating layer 20. An upper surface of the second insulating layer 20 may be a flat surface.

The conductive pattern SMP may be disposed between the first transistor Tr-B and the second transistor Tr-T. At least one insulating layer may be disposed between the first transistor Tr-B and the conductive pattern SMP, and at least one insulating layer may be disposed between the conductive pattern SMP and the second transistor Tr-T.

Referring to FIG. 7 and the like, the conductive pattern SMP may be disposed on the second insulating layer 20 and covered through the third insulating layer 30. The conductive pattern SMP may be spaced apart from the first transistor Tr-B with the second insulating layer 20 therebetween in the third direction DR3, and may also be spaced apart from the second transistor Tr-T with the third insulating layer 30 therebetween in the third direction DR3.

The conductive pattern SMP may be electrically connected to a voltage line SL-P through a contact hole defined in the third to fifth insulating layers 30, 40, and 50. For example, the voltage line SL-P electrically connected to the conductive pattern SMP may be a line to which a constant voltage is applied. For example, the conductive pattern SMP may be electrically connected to a constant voltage line. A predetermined DC voltage may be applied to the conductive pattern SMP through the voltage line SL-P.

The second source S-T, the second drain D-T, and the second upper electrode G-UP of the second transistor Tr-T may be electrically connected to electrodes or signal lines through a second contact hole CH-U defined in the fifth insulating layer 50. The second source S-T may be electrically connected to the second source electrode SE-T, the second drain D-T may be electrically connected to the second drain electrode DE-T, and the second upper electrode G-UP may be electrically connected to the second gate line SL-GU. The lower electrode G-BP of the second transistor Tr-T may be electrically connected to an upper line SL-U through a contact hole defined in the fourth insulating layer 40 and the fifth insulating layer 50. The upper line SL-U may be a signal line connected to the lower electrode G-BP. The upper line SL-U may transmit signals to the lower electrode G-BP of the second transistor Tr-T. The lower electrode G-BP of the second transistor Tr-T may be electrically connected to the upper semiconductor pattern A-T. In another embodiment, the lower electrode G-BP of the second transistor Tr-T may be electrically connected to the second upper electrode G-UP. An upper connection line UCL may be electrically connected to the lower line SL-L through the second to fifth insulating layers 20, 30, 40, and 50. The upper connection line UCL may be electrically connected to the lower line SL-L, and may also be electrically connected to the lower shielding pattern BML.

The voltage line SL-P, the upper line SL-U, the second source electrode SE-T, the second drain electrode DE-T, the second gate line SL-GU, and the upper connection line UCL may be covered through the upper insulating layer 60.

The conductive pattern SMP may overlap at least a portion of each of the lower semiconductor pattern A-B and the upper semiconductor pattern A-T in the third direction DR3. The conductive pattern SMP may be disposed between the lower semiconductor pattern A-B and the upper semiconductor pattern A-T that overlap each other. The conductive pattern SMP may include a metal, a metal oxide, or a transparent conductive material.

Referring to FIGS. 7 and 8A, the conductive pattern SMP may overlap the lower semiconductor pattern A-B in a plan view defined by a first directional axis DR1 and a second directional axis DR2. The conductive pattern SMP may cover an entire region of the lower semiconductor pattern A-B. The conductive pattern SMP may cover the first transistor Tr-B.

Referring to FIGS. 7 to 8B, the conductive pattern SMP may overlap the lower semiconductor pattern A-B and the upper semiconductor pattern A-T in a plan view defined by the first directional axis DR1 and the second directional axis DR2. The upper semiconductor pattern A-T may overlap (or entirely overlap) the lower semiconductor pattern A-B in the third direction DR3. The channel C-T of the upper semiconductor pattern A-T may overlap the channel C-B of the lower semiconductor pattern A-B in the third direction DR3.

Referring to FIGS. 8A and 8B, the conductive pattern SMP may overlap an entire portion of the lower semiconductor pattern A-B and the upper semiconductor pattern A-T in a plan view. Meanwhile, although an area of the upper semiconductor pattern A-T in FIG. 8B and the like is shown to be smaller than an area of the lower semiconductor pattern A-B, the embodiment of the disclosure is not limited thereto, and the area of the lower semiconductor pattern A-B may be larger than what is shown, and for example, the lower semiconductor pattern A-B may overlap the conductive pattern SMP in the third direction DR3.

The conductive pattern SMP may be disposed to overlap the first semiconductor pattern A-B and the second semiconductor pattern A-T to prevent coupling between the first transistor Tr-B and the second transistor Tr-T, thereby enabling a display device to exhibit good electrical characteristics and driving characteristics even in case that transistors controlled and operated differently are aligned in a vertical direction.

The display panel 100 according to an embodiment may include a first pixel transistor T1 and a second pixel transistor T2. Referring to FIG. 6, the first pixel transistor T1 and the second pixel transistor T2 may be disposed in the display region DA. However, the embodiment of the disclosure is not limited thereto, and some of multiple pixel transistors may be disposed in the non-display region NDA.

The first pixel transistor T1 may be connected to the light emitting element ED. The first pixel transistor T1 may be a driving transistor. The second pixel transistor T2 may be electrically connected to the first pixel transistor T1. The second pixel transistor T2 may be a switching transistor.

The first pixel transistor T1 may include a third semiconductor pattern A1 and a first gate G1. The third semiconductor pattern A1 may be divided into a third source (or third source region, S1), a third channel (or third channel region, C1), and a third drain (or third drain region, D1). A first insulating pattern GI1 may be disposed between the third semiconductor pattern A1 and the first gate G1. The first gate G1 may be disposed on the first insulating pattern GI1 and may be spaced apart from the third semiconductor pattern A1 in the third direction DR3. The first gate G1 may overlap the third channel C1 in the third direction DR3. For example, a width of the third channel C1 may be determined to correspond to the first gate G1.

The third source S1 and the third drain D1 of the first pixel transistor T1 may be electrically connected to electrodes or signal lines through a contact hole defined in the first insulating layer 10. The third source S1 may be electrically connected to the third source electrode SE1, and the third drain D1 may be electrically connected to the third drain electrode DE1. Meanwhile, the third source electrode SE1 may be electrically connected to the lower shielding pattern BML through a contact hole defined in the buffer layer BFL and the first insulating layer 10. The third source electrode SE1 may be electrically connected to the light emitting element ED through the connection electrode CNE. The third source electrode SE1 and the third drain electrode DE1 may be covered through the second insulating layer 20.

The second pixel transistor T2 may include a fourth semiconductor pattern A2 and a second gate G2. The fourth semiconductor pattern A2 may be divided into a fourth source (or fourth source region, S2), a fourth channel (or fourth channel region, C2), and a fourth drain (or fourth drain region, D2). A second insulating pattern GI2 may be disposed between the fourth semiconductor pattern A2 and the second gate G2. The second gate G2 may be disposed on the second insulating pattern GI2 and may be spaced apart from the fourth semiconductor pattern A2 in the third direction DR3. The second gate G2 may overlap the fourth channel C2 in the third direction DR3. For example, a width of the fourth channel C2 may be determined to correspond to the second gate G2.

The fourth source S2 and the fourth drain D2 of the second pixel transistor T2 may be connected to electrodes or signal lines through a contact hole defined in the first insulating layer 10. The fourth source S2 may be connected to the fourth source electrode SE2, and the fourth drain D2 may be connected to the fourth drain electrode DE2. Meanwhile, the fourth source electrode SE2 may be electrically connected to the lower shielding pattern BML through a contact hole defined in the buffer layer BFL and the first insulating layer 10. The fourth source electrode SE2 may be electrically connected to the upper signal line USL through a contact hole defined in the second to fifth insulating layers 20, 30, 40, and 50. The fourth source electrode SE2 and the fourth drain electrode DE2 may be covered through the second insulating layer 20.

The first pixel transistor T1 and the second pixel transistor T2 may be disposed on the same layer. However, the embodiment of the disclosure is not limited thereto, and the semiconductor pattern A1 of the first pixel transistor T1 and the semiconductor pattern A2 of the second pixel transistor T2 may be disposed on different layers, or the first pixel transistor T1 and the second pixel transistor T2 may be disposed to overlap in the third direction DR3. For example, a conductive pattern may be further disposed between the first pixel transistor T1 and the second pixel transistor T2.

The display device of an embodiment may have multiple transistors disposed to overlap vertically, thereby reducing an area for disposing the transistors, and may maintain excellent driving characteristics even in case that the transistors are disposed to overlap. In case that multiple circuits for providing driving signals to pixels of one row or one column need to be disposed in the corresponding row or column, transistors constituting multiple circuits may be disposed to overlap vertically, thereby reducing intervals between rows or columns for disposing multiple transistors, resulting in reduced arrangement intervals between pixels. Accordingly, the display device of an embodiment may exhibit high resolution.

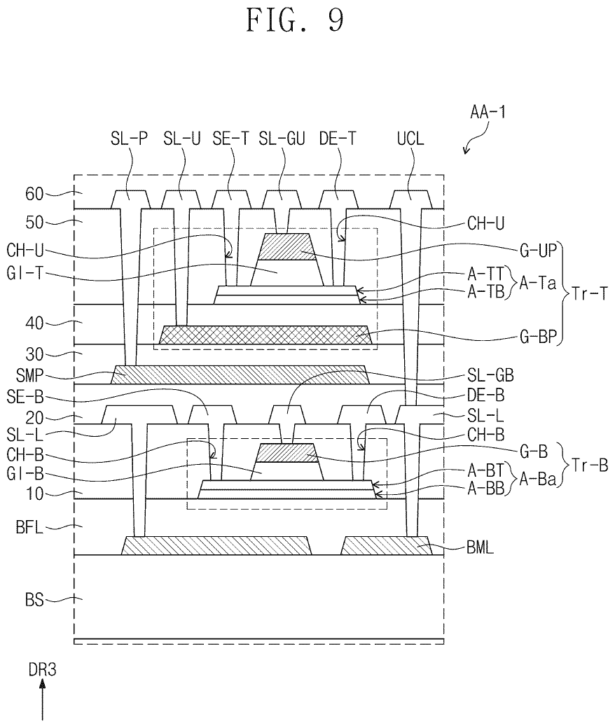

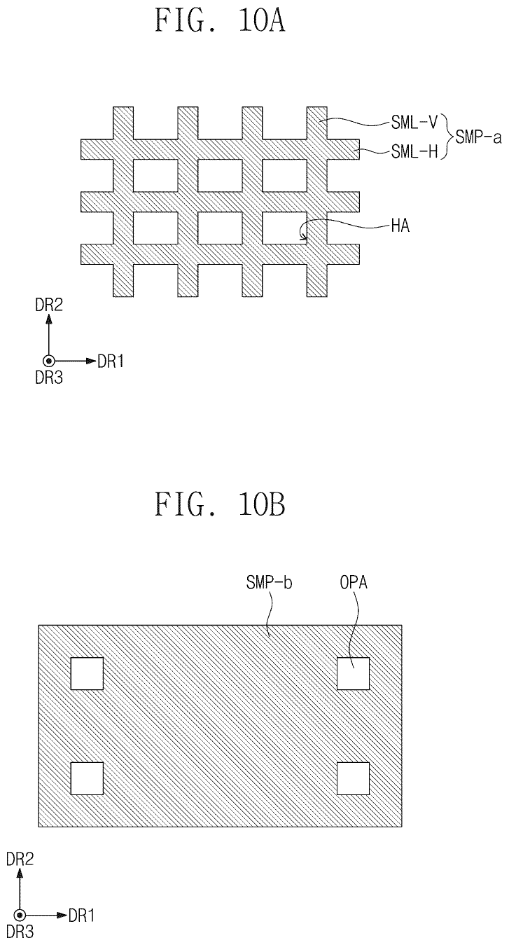

Hereinafter, a display panel according to an embodiment and a display device of an embodiment will be described with reference to FIGS. 9 to 16. Hereinafter, in the description of FIGS. 9 to 16, redundant descriptions described with reference to FIGS. 1 to 8B will not be provided again, and differences will be mainly described.

Region AA-1 shown in FIG. 9 may correspond to region AA of FIG. 6. FIG. 9 shows a cross-section showing a portion of a display panel according to an embodiment. In FIG. 9, a source region, a channel region, and a drain region are not distinguished in semiconductor patterns, but the descriptions of regions distinguished in the semiconductor patterns as in FIGS. 6 and 7 may be applied.

Referring to FIG. 9, a lower semiconductor pattern A-Ba may include two stacked semiconductor pattern layers A-BB and A-BT. A first lower semiconductor layer A-BB and a second lower semiconductor layer A-BT may each be an oxide semiconductor layer. The first lower semiconductor layer A-BB and the second lower semiconductor layer A-BT may have the same oxide semiconductor material composition or may have different oxide semiconductor material compositions.

An upper semiconductor pattern A-Ta may include two stacked semiconductor pattern layers A-TB and A-TT. A first upper semiconductor layer A-TB and the second upper semiconductor layer A-TT may each be an oxide semiconductor layer. The first upper semiconductor layer A-TB and the second upper semiconductor layer A-TT may have the same oxide semiconductor material composition or may have different oxide semiconductor material compositions.

Meanwhile, FIG. 9 may show that the first transistor Tr-B and the second transistor Tr-T each include a semiconductor pattern including two stacked semiconductor layers, but the embodiment of the disclosure is not limited thereto, and either the lower semiconductor pattern A-Ba or the upper semiconductor pattern A-Ta may have a structure in which multiple semiconductor layers are stacked, and the other may have a structure having a single layer. Each of the first transistor Tr-B and the second transistor Tr-T may have a structure in which three or more layers are stacked.

The semiconductor patterns A-Ba and A-Ta have a structure in which multiple semiconductor layers are stacked, and accordingly, electron mobility in the semiconductor patterns A-Ba and A-Ta may increase through a material combination of the semiconductor layers.

FIGS. 10A and 10B are schematic plan views each showing an embodiment of a conductive pattern. FIGS. 10A and 10B each may show an embodiment of a conductive pattern, and the conductive pattern may have a form in which portions of open regions HA and OPA in which a conductive material is not disposed in at least a partial region are defined.

Referring to FIG. 10A, a conductive pattern SMP-a according to an embodiment may have a lattice pattern including a horizontal line portion SML-H extending in a direction in a plan view and a vertical line portion SML-V crossing the horizontal line portion SML-H. An opening pattern HA may be defined by the cross arrangement of the horizontal line portion SML-H and the vertical line portion SML-V.

Referring to FIG. 10B, at least one hole OPA may be defined in a conductive pattern SMP-b according to an embodiment. The hole OPA may be formed as passing through the conductive pattern SMP-b.

FIGS. 10A and 10B may show an embodiment of a conductive pattern, and the shape of the conductive pattern is not limited to what is shown. The conductive patterns SMP-a and SMP-b according to an embodiment shown in FIGS. 10A and 10B may correspond to ones in which at least a partial region is defined as portions of open regions, and accordingly, the case may have a lower chance of the conductive pattern being peeled compared to a case in which the conductive patterns SMP-a and SMP-b are provided entirely without open regions. For example, the conductive patterns SMP-a and SMP-b provided to have a thin film thickness may be exposed to a risk of peeling in this case a provided area is large, and thus in this case the opening pattern HA or the hole OPA is defined in the conductive patterns SMP-a and SMP-b, stress provided to the conductive patterns SMP-a and SMP-b may be reduced, increasing the bonding strength with adjacent insulating layers.

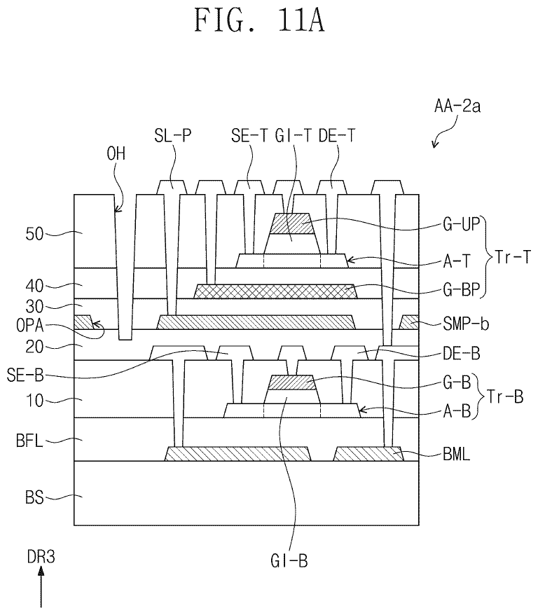

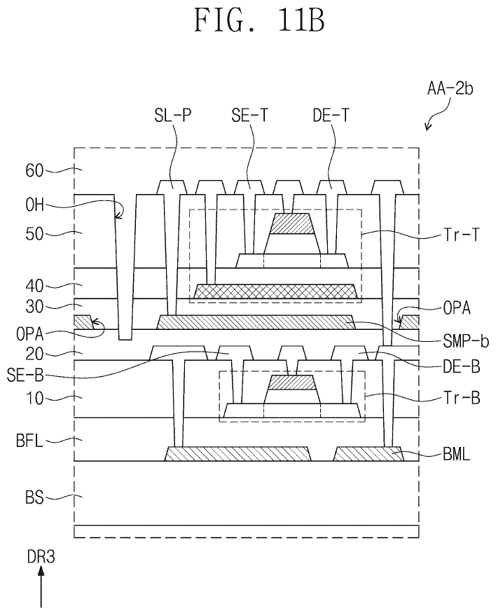

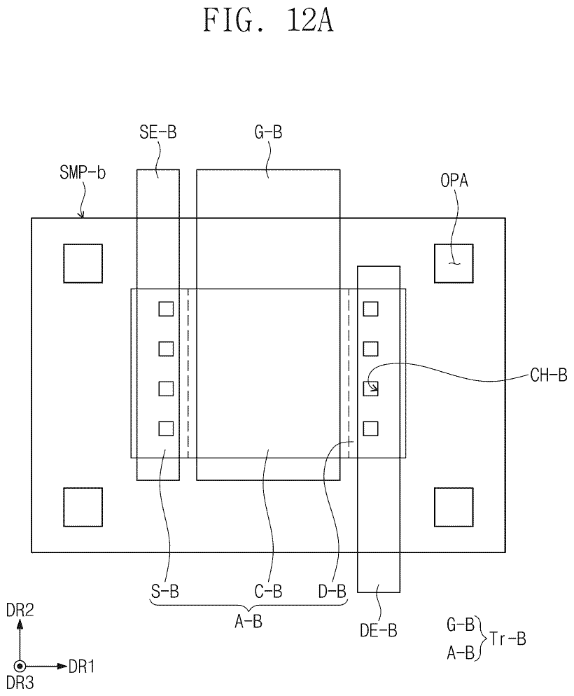

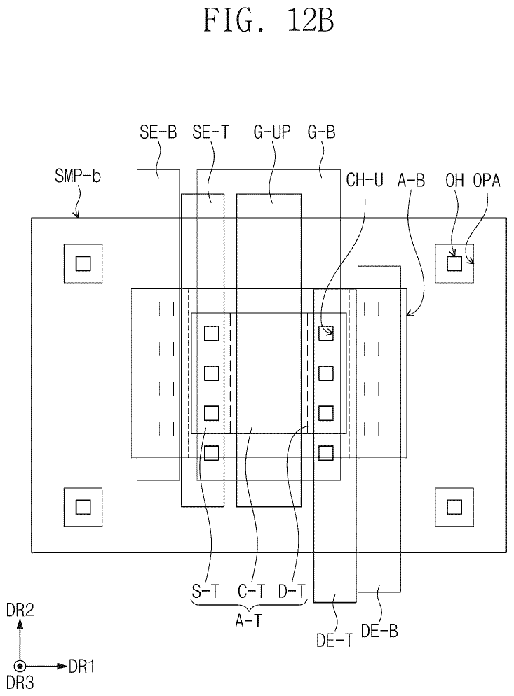

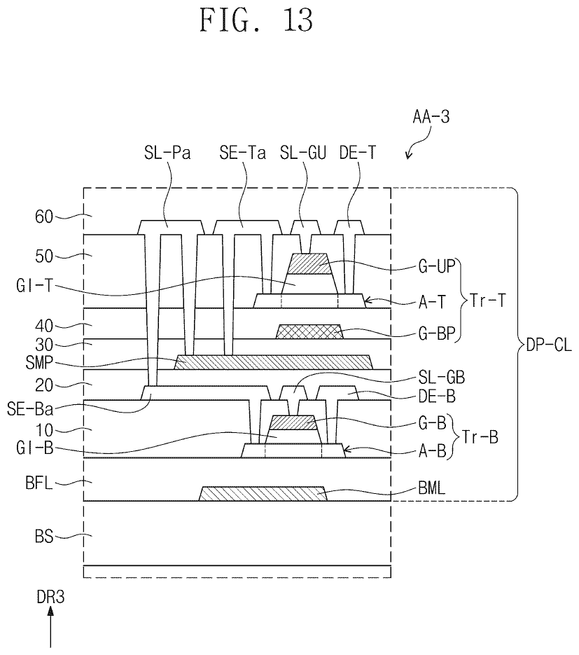

FIGS. 11A and 11B are schematic cross-sectional views each showing a portion of a display panel according to an embodiment, and FIGS. 12A and 12B are schematic plan views each showing a portion of a display panel according to an embodiment.

FIG. 11B is a schematic cross-sectional view showing a case in which an upper insulating layer 60 is added to FIG. 11A, and region AA-2a of FIG. 11A and region AA-2b of FIG. 11B may each be portions corresponding to region AA region of FIG. 6. FIGS. 12A and 12B may be schematic plan views showing a partial region of a portion corresponding to region AA-2b shown in FIG. 11B. FIG. 12A shows, as an example, a plane in which the conductive pattern SMP-b is disposed on the first transistor Tr-B and the first transistor Tr-B, and FIG. 12B shows, as an example, a plane in which the second transistor Tr-T is disposed on a stack structure of the first transistor Tr-B and the conductive pattern SMP-b in FIG. 12A. In FIGS. 12A and 12B, the stack structure is shown without a portion thereof, and the overlapping relationship between the semiconductor pattern of the first transistor Tr-B, the conductive pattern SMP-b, and the semiconductor pattern of the second transistor Tr-T is mainly shown.

A display panel according to an embodiment may include a hole region defined to pass through two or more insulating layers among stacked insulating layers included in a circuit layer. Referring to FIGS. 11A and 11B, in the display panel according to an embodiment, a hole region OH may be defined to pass through the third to fifth insulating layers 30, 40, and 50 and may extend to a portion of an upper portion of the second insulating layer 20. The hole region OH may be defined in the insulating layers, and a conductive pattern, a semiconductor pattern, a line, and the like may non-overlap in the hole region OH. The hole region OH formed to pass through the insulating layers may have a contact hole shape, but no conductive material may be disposed in the hole region OH, and thus the hole region OH may be referred to as a dummy contact hole.

In FIGS. 11A and 11B, an embodiment in which the hole region OH is formed integrally from the second insulating layer 20 to the fifth insulating layer 50 may be shown, but the embodiment of the disclosure is not limited thereto, and the hole region OH may be formed to pass through from any one of the first to fourth insulating layers 10, 20, 30, and 40 to the upper insulating layers. For example, the hole region OH may be defined as passing through from any one of the first to fourth insulating layers 10, 20, 30, and 40 to the fifth insulating layer 50.

The hole region OH may be filled with a material of an upper insulating layer in which a hole region is not defined. Referring to FIG. 11B and the like, the hole region OH may be filled with the upper insulating layer 60.

The hole region OH may non-overlap the conductive pattern SMP-b. The hole OPA may be defined to overlap the hole region OH in the conductive pattern SMP-b.

The display device may include a hole region OH that is not covered with a metal or a conductive material in a circuit layer, and may thus induce outgas generated from insulating layers or a lower portion the insulating layers at high temperatures during a display panel manufacturing process to be discharged without being transmitted to transistors or a conductive pattern. For example, a display panel according to an embodiment, which includes the hole region OH that is not covered with a metal and a conductive material layer of a circuit layer of a conductive pattern and a transistor and is formed as passing through multiple insulating layers, may induce outgas to be easily discharged through the hole region OH, obtaining the reliability of the conductive pattern and the transistor. Therefore, the display device of an embodiment may exhibit excellent reliability and driving characteristics.

Referring to FIGS. 12A and 12B, the conductive pattern SMP-b may overlap an entire portion of the lower semiconductor pattern A-B and the upper semiconductor pattern A-T in a plan view. Meanwhile, although an area of the upper semiconductor pattern A-T in FIG. 12B and the like is shown to be smaller than an area of the lower semiconductor pattern A-B, the embodiment of the disclosure is not limited thereto, and the area of the lower semiconductor pattern A-B may be larger than what is shown, and for example, the lower semiconductor pattern A-B may overlap the conductive pattern SMP-b.

The conductive pattern SMP-b may be disposed to overlap the first semiconductor pattern A-B and the second semiconductor pattern A-T to prevent coupling between the first transistor Tr-B and the second transistor Tr-T, thereby enabling a display device to exhibit good electrical characteristics and driving characteristics even in this case transistors controlled and operated differently are aligned in a vertical direction. The conductive pattern SMP-b may include the hole OPA defined to overlap an entire portion of the hole region OH formed as passing through insulating layers to prevent a conductive layer from being covered in the hole region OH, and may thus induce outgas at a lower side to easily discharged through the hole region OH. Accordingly, the display device of an embodiment has greater adhesive strength of the conductive pattern SMP-b through the hole OPA defined in the conductive pattern SMP-b and exhibit facilitated discharge of gas generated during the manufacturing process through the hole region OH overlapping the hole OPA, may thus exhibit excellent reliability characteristics.

FIG. 13 is a schematic cross-sectional view showing a display panel according to an embodiment. Region AA-3 of FIG. 13 may correspond to region AA of FIGS. 6 and 7. Referring to FIG. 13, the display panel according to an embodiment may be different in the form of electrodes or lines connected to the lower shielding pattern BML, the first transistor Tr-B, the second transistor Tr-T, or the conductive pattern SMP through contact holes of insulating layers, from the display panel of FIG. 7.

The conductive pattern SMP may be electrically connected to a voltage line SL-Pa to which a constant voltage is applied, and further, the conductive pattern SMP may be electrically connected to at least one of the first semiconductor pattern A-B or the second semiconductor pattern A-T. Referring to FIG. 13, the voltage line SL-Pa may be electrically connected to the conductive pattern SMP and a first source electrode SE-Ba. Accordingly, the conductive pattern SMP may be electrically connected to the voltage line SL-Pa, which is a constant voltage line, and may be electrically connected to the first semiconductor pattern A-B. A second source electrode SE-Ta may be electrically connected to the second semiconductor pattern A-T and the conductive pattern SMP. Meanwhile, unlike what is shown in FIG. 13, the conductive pattern SMP may be electrically connected to only one of the first semiconductor pattern A-B and the second semiconductor pattern A-T.

Even in this case the conductive pattern SMP is electrically connected to at least one of the first semiconductor pattern A-B or the second semiconductor pattern A-T, a predetermined DC voltage of the conductive pattern SMP may applied and coupling between the first transistor Tr-B and the second transistor Tr-T may be prevented through the conductive pattern SMP.

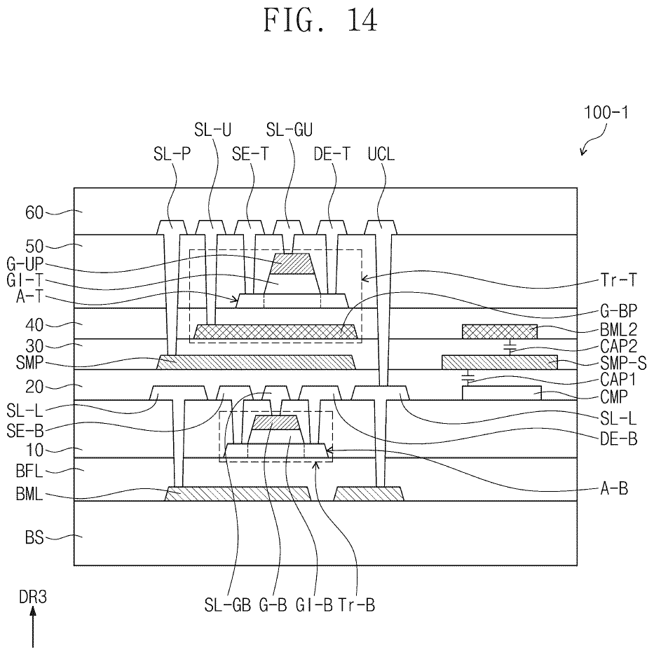

FIG. 14 is a schematic cross-sectional view of a portion of a display panel according to an embodiment. A display panel 100-1 according to the embodiment shown in FIG. 14 may differ from the display panel 100 of the embodiment shown in FIG. 6 in that the display panel 100-1 further includes capacitors CAP1 and CAP2.

In the display panel 100 of an embodiment, the circuit layer DP-CL may further include capacitors CAP1 and CAP2 including a first sub-conductive pattern SMP-S disposed on the same layer as the conductive pattern SMP and may include the same material as the conductive pattern SMP, and a second sub-conductive patterns BML2 and CMP overlapping the first sub-conductive pattern SMP-S in the third direction DR3 and disposed above or below the first sub-conductive pattern SMP-S.

Referring to FIG. 14, an embodiment may include at least one of a first auxiliary capacitor CAP1 including a (2-1)-th sub-conductive pattern BML2 and the first sub-conductive pattern SMP-S, and a second auxiliary capacitor CAP2 including a (2-2)-th sub-conductive pattern CMP and the first sub-conductive pattern SMP-S. Meanwhile, the second sub-conductive pattern BML2 and CMP may be disposed on the same layer as the semiconductor pattern or the upper electrode or the lower electrode, as an example of a stack structure of the second sub-conductive pattern BML2 and CMP shown in FIG. 14.

For example, the display device of an embodiment further includes a capacitor composed of the first sub-conductive pattern SMP-S disposed on the same layer as the conductive pattern SMP, and the second sub-conductive pattern BML2 and CMP disposed on the same layer as other conductive layers, lines, and electrode patterns included in the circuit layer DP-CL, and may thus exhibit an increase in storage cap (capacitance).

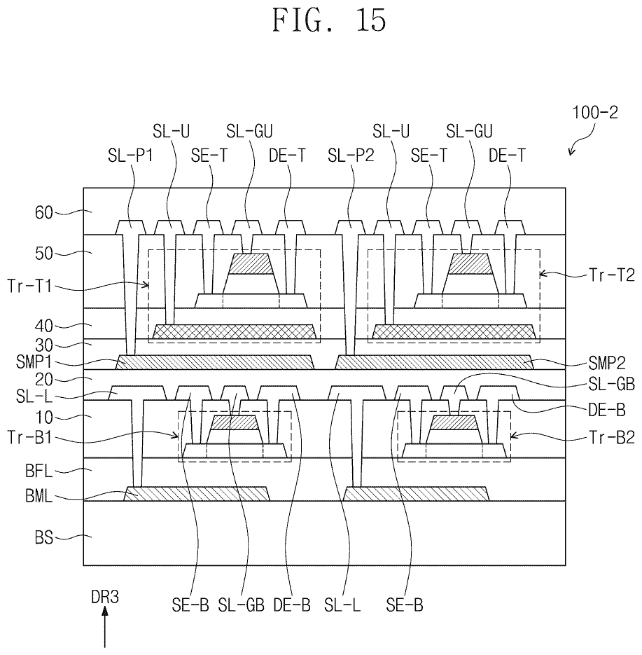

FIG. 15 is a schematic cross-sectional view showing a portion of a display panel according to an embodiment. Referring to FIG. 15, a display panel 100-2 of an embodiment may include multiple sets of transistors disposed to overlap vertically.

The display panel 100-2 of an embodiment may include a (1-1)-th transistor Tr-B1 and a (2-1)-th transistor Tr-T1 disposed to overlap in the third direction DR3, and a (1-2)-th transistor Tr-B2 and a (2-2)-th transistor Tr-T2 disposed to overlap in the third direction DR3. The semiconductor patterns of the (1-1)-th transistor Tr-B1 and the (2-1)-th transistor Tr-T1 may overlap, and the semiconductor patterns of the (1-2)-th transistor Tr-B2 and the (2-2)-th transistor Tr-T2 may overlap.

In the display panel 100-2 of an embodiment, the (1-1)-th transistor Tr-B1 and the (1-2)-th transistor Tr-B2 may be disposed on the same layer, and the (2-1)-th transistor Tr-T1 and the (2-2)-th transistor Tr-T2 may be disposed on the same layer. However, the embodiment of the disclosure is not limited thereto, and any stack structure in which the (1-1)-th transistor Tr-B1 and the (2-1)-th transistor Tr-T1 overlap, and the (1-2)-th transistor Tr-B2 and the (2-2)-th transistor Tr-T2 overlap may be used without limitation.

A first conductive pattern SMP1 may be disposed between the (1-1)-th transistor Tr-B1 and the (2-1)-th transistor Tr-T1. The first conductive pattern SMP1 may overlap the semiconductor pattern of the (1-1)-th transistor Tr-B1 and the semiconductor pattern of the (2-1)-th transistor Tr-T1. The first conductive pattern SMP1 may be electrically connected to a first voltage line SL-P1. A predetermined constant voltage may be applied to the first conductive pattern SMP1 through the first voltage line SL-P1.

A second conductive pattern SMP2 may be disposed between the (1-2)-th transistor Tr-B2 and the (2-2)-th transistor Tr-T2. The second conductive pattern SMP2 may overlap the semiconductor pattern of the (1-2)-th transistor Tr-B2 and the semiconductor pattern of the (2-2)-th transistor Tr-T2. The second conductive pattern SMP2 may be electrically connected to a second voltage line SL-P2. A predetermined constant voltage may be applied to the second conductive pattern SMP2 through the second voltage line SL-P2.

Different constant voltage lines may be electrically connected to the first conductive pattern SMP1 and the second conductive pattern SMP2. A DC voltage provided to the first voltage line SL-P1 connected to the first conductive pattern SMP1 and a DC voltage provided to the second voltage line SL-P2 connected to the second conductive pattern SMP2 may have different voltage levels.

The second conductive pattern SMP2 may be spaced apart from the first conductive pattern SMP1 in a plan view. A display panel 100-3 of an embodiment may include multiple conductive patterns distinguished from one another, and multiple conductive patterns may be disposed to be spaced apart in a plan view. Different constant voltage lines may be electrically connected to each of the conductive patterns.

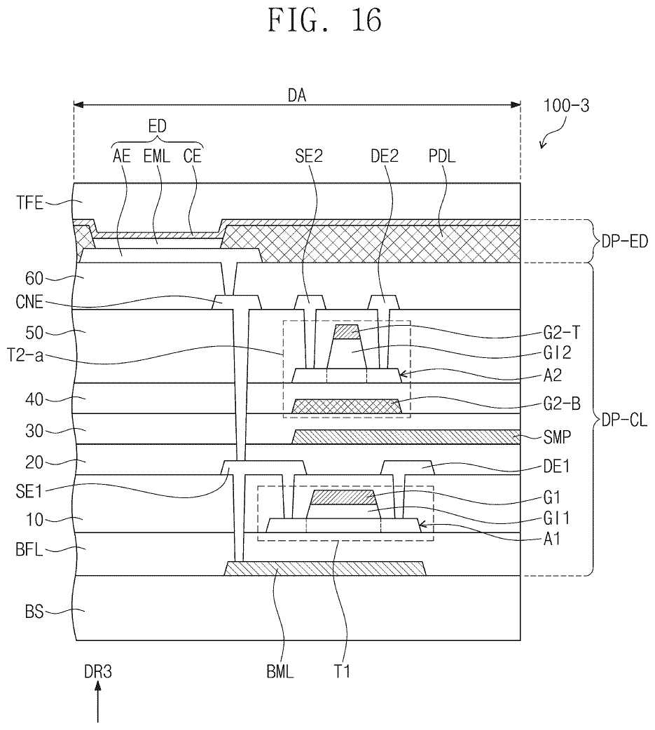

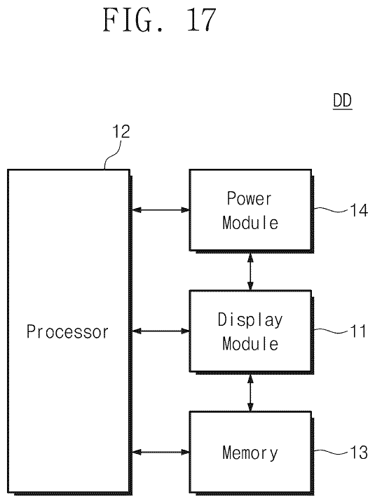

FIG. 16 is a schematic cross-sectional view showing a portion of a display panel of an embodiment. FIG. 16 shows a portion of a display region DA of a display panel 100-3. FIG. 16 may be a portion corresponding to the display region of FIG. 6.

In the display panel 100-3 according to an embodiment, multiple transistors constituting a pixel circuit may be disposed to overlap in the third direction DR3. Referring to FIG. 16, a first pixel transistor T1 and a second pixel transistor T2-a may be disposed to overlap in the third direction DR3 in the third direction DR3. The first pixel transistor T1 may be a driving transistor connected to the light emitting element ED, and the second pixel transistor T2-a may be a switching transistor electrically connected to the first pixel transistor T1.

The first pixel transistor T1 may include a semiconductor pattern (third semiconductor pattern, A1) and a gate (third gate, G1). A first insulating pattern GI1 may be disposed between the semiconductor pattern (third semiconductor pattern, A1) and the gate (third gate, G1). A source electrode SE1 and a drain electrode DE1 may be electrically connected to the semiconductor pattern A1. The source electrode SE1 of the first pixel transistor T1 may be electrically connected to the light emitting element ED through the connection electrode CNE.

The second pixel transistor T2-a may include a semiconductor pattern (fourth semiconductor pattern, A2), an upper gate G2-T, and a lower gate G2-B. A second insulating pattern GI2 may be disposed between the semiconductor pattern (fourth semiconductor pattern, A2) and the upper gate G2-T. A source electrode SE2 and a drain electrode DE2 may be electrically connected to the semiconductor pattern A2.

Meanwhile, at least one semiconductor pattern of the first pixel transistor T1 and the second pixel transistor T2 may include a metal oxide. The first pixel transistor T1 and the second pixel transistor T2 may include oxide semiconductor patterns having the same composition, or may include oxide semiconductor patterns having different material components or different material ratios.

The semiconductor pattern (third semiconductor pattern, A1) of the first pixel transistor T1 may overlap the semiconductor pattern (fourth semiconductor pattern, A2) of the second pixel transistor T2-a. The conductive pattern SMP may be disposed on the first pixel transistor T1 and the second pixel transistor T2-a. The conductive pattern SMP may be referred to as a pixel portion conductive pattern. The conductive pattern SMP may overlap the semiconductor pattern (or third semiconductor pattern, A1) of the first pixel transistor T1 and the semiconductor pattern (or fourth semiconductor pattern, A2) of the second pixel transistor T2-a. Although not shown in FIG. 16, the conductive pattern SMP may be electrically connected to a voltage line, and a predetermined constant voltage may be applied to the conductive pattern SMP.

The conductive pattern SMP may be disposed to overlap the semiconductor pattern (or third semiconductor pattern, A1) of the first pixel transistor T1 and the semiconductor pattern (or fourth semiconductor pattern, A2) of the second pixel transistor T2-a, and accordingly, even in this case the first pixel transistor T1 and the second pixel transistor T2-a are disposed to overlap vertically, coupling may not take place, and thus the display device of an embodiment may exhibit excellent driving characteristics.

In FIG. 16, only the stack arrangement form of pixel transistors T1 and T2-a may be shown, but as described with reference to FIGS. 6 to 15, in addition to pixel transistors, a structure in which other transistors are disposed to overlap vertically may also be included. Accordingly, the display device of an embodiment has transistors disposed to overlap vertically, and thus may reduce an area for disposing the transistors, increase an area of a display portion (light emitting region), and reduce an area of a non-display portion (non-light emitting region, dead space, and the like), thereby exhibiting enhanced display quality and resolution characteristics.

The display device of an embodiment may include a lower transistor and an upper transistor disposed to overlap vertically, and may include a conductive pattern disposed to overlap both a semiconductor pattern of the lower transistor and a semiconductor pattern of the upper transistor between the lower transistor and the upper transistor. Accordingly, the display device of an embodiment may reduce a space for disposing transistors to minimize dead space, and may reduce an arrangement interval between pixels by disposing transistors in an integrated manner to achieve high resolution. The display device of an embodiment may have a conductive pattern disposed between transistors to prevent coupling between transistors, and may thus exhibit excellent electrical characteristics and driving characteristics.

A display device of an embodiment may include transistors disposed to overlap in a plan view, and may thus minimize dead space by reducing an area for disposing multiple transistors.

A display device of an embodiment may include transistors disposed to overlap and conductive patterns disposed between the overlapping semiconductor patterns, and may thus minimize dead space, exhibit high resolution characteristics, and reduce coupling noise between semiconductor patterns.

FIG. 17 is a block diagram of an electronic device according to an embodiment. Referring to FIG. 17, an electronic device DD according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen. The display module 11 may include a display panel which displays an image.

The power module 14 may include a power supply module such as a power adapter or a battery device, and a power conversion module which converts the power supplied by the power supply module and generates power necessary for an operation of the electronic device DD.

At least one of the components of the electronic device DD described above may be included in a display device including the display panel according to an embodiment, described later. In addition, some of individual modules included as functional in one module may be included in the display device, and others may be provided separately from the display device. For example, the display device may include the display module 11, and the processor 12, the memory 13, and the power module 14 may be provided not in the display device but in another type of device in the electronic device DD.

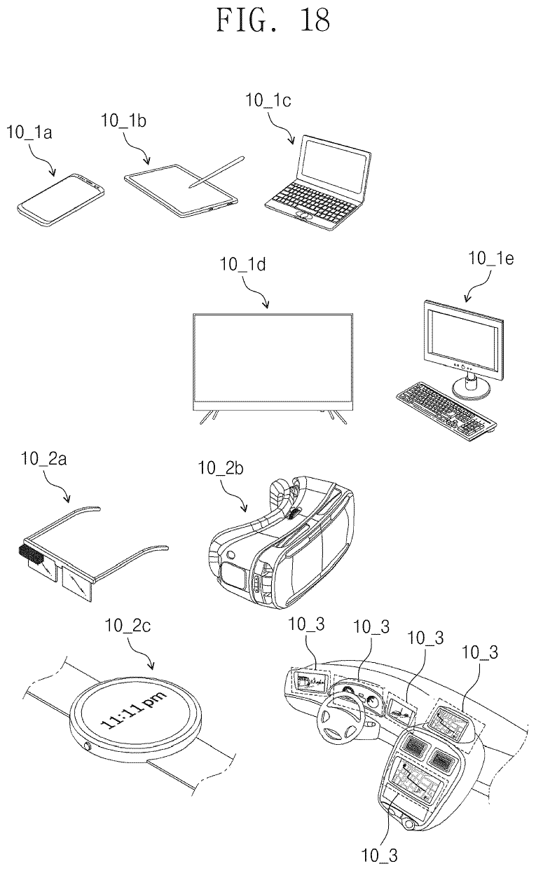

FIG. 18 illustrates schematic views of electronic devices according to various embodiments.

Referring to FIG. 18, various electronic devices including a display device according to an embodiment may include not only an electronic device for image display, e.g., a smartphone 10_1a, a tablet computer (PC) 10_1b, a laptop computer 10_1c, TV 10_1d, and a monitor for a desk computer 10_1e, but also a wearable electronic device including a display module, e.g., smart glasses 10_2a, a head mounted display 10_2b, and a smart watch 10_2c, and an electronic device for vehicle 10_3 including a display module, e.g., a vehicle instrument panel, a center fascia, a center information display (CID) disposed on a dashboard, and a room mirror display.

Although the disclosure has been described with reference to a preferred embodiment of the disclosure, it will be understood that the disclosure should not be limited to these preferred embodiments but various changes and modifications may be made by those skilled in the art without departing from the spirit and scope of the disclosure.

Accordingly, the technical scope of the disclosure is not intended to be limited to the contents set forth in the detailed description of the specification, but is intended to be defined by the appended claims.

What is claimed is:

1. A display device comprising:
a base layer;
a circuit layer disposed on the base layer and including a first transistor, a second transistor disposed on the first transistor, and a conductive pattern disposed between the first transistor and the second transistor; and
a display layer disposed on the circuit layer and including a light emitting element,
wherein the first transistor includes a first semiconductor pattern and a first upper electrode disposed on the first semiconductor pattern,
the second transistor includes a second semiconductor pattern, a second upper electrode disposed on the second semiconductor pattern, and a lower electrode disposed below the second semiconductor pattern,
the first semiconductor pattern and the second semiconductor pattern overlap, and
the conductive pattern at least partially overlaps each of the first semiconductor pattern and the second semiconductor pattern.

2. The display device of claim 1, wherein at least one of the first semiconductor pattern or the second semiconductor pattern comprises an oxide semiconductor.

3. The display device of claim 2, wherein the oxide semiconductor has a mobility of about 20 cm²/Vs or greater.

4. The display device of claim 2, wherein
the oxide semiconductor is a metal oxide containing indium, gallium, and zinc, and
the content of indium in the metal oxide is at least twice the content of gallium.

5. The display device of claim 2, wherein at least one of the first semiconductor pattern or the second semiconductor pattern is stacked in a thickness direction, and comprises a plurality of layers having different oxide semiconductor material compositions.

6. The display device of claim 1, wherein the conductive pattern comprises a metal, a metal oxide, or a transparent conductive material.

7. The display device of claim 1, wherein
the conductive pattern is electrically connected to a constant voltage line, and
the lower electrode is electrically connected to the second semiconductor pattern or the second upper electrode.

8. The display device of claim 1, wherein the conductive pattern comprises a lattice pattern including a horizontal line portion extending in a direction in a plan view and a vertical line portion crossing the horizontal line portion.

9. The display device of claim 1, wherein at least one hole is defined in the conductive pattern.

10. The display device of claim 1, wherein the circuit layer further comprises a first insulating layer covering the first semiconductor pattern, a second insulating layer disposed between the first insulating layer and the conductive pattern, a third insulating layer disposed between the conductive pattern and the lower electrode, a fourth insulating layer covering the lower electrode, a fifth insulating layer covering the second semiconductor pattern, and an upper insulating layer disposed on the fifth insulating layer.

11. The display device of claim 10, wherein
a hole region is defined as passing through from any one of the first to fourth insulating layers to the fifth insulating layer, and
the upper insulating layer is filled in the hole region.

12. The display device of claim 10, wherein at least one of an upper surface of the second insulating layer or an upper surface of the third insulating layer is a flat surface.

13. The display device of claim 1, wherein
the conductive pattern is provided in plurality distinguished from one another,
the plurality of conductive patterns are disposed to be spaced apart in a plan view, and
the plurality of conductive patterns are each electrically connected to different constant voltage lines.

14. The display device of claim 1, wherein
a constant voltage is applied to the conductive pattern, and
the conductive pattern is electrically connected to at least one of the first semiconductor pattern or the second semiconductor pattern.

15. The display device of claim 1, wherein
the circuit layer further comprises a capacitor including:
a first sub-conductive pattern, and
a second sub-conductive pattern overlapping the first sub-conductive pattern and disposed above or below the first sub-conductive pattern, and
the first sub-conductive pattern and the conductive pattern are disposed on a same layer, and
the first sub-conductive pattern and the conductive pattern include a same material.

16. An electronic device divided into a display region and a non-display region disposed on a side of the display region, comprising:
a base layer;
a display layer disposed on the base layer and including a plurality of light emitting elements corresponding to the display region; and
a circuit layer disposed between the base layer and the display layer and including a plurality of transistors and a plurality of insulating layers,
wherein the circuit layer includes:
a pixel circuit electrically connected to the light emitting elements; and
a gate driving circuit disposed in the non-display region and including a lower transistor, an upper transistor disposed on the lower transistor, and a conductive pattern disposed between the lower transistor and the upper transistor,
the lower transistor includes a first semiconductor pattern and a first upper electrode disposed on the first semiconductor pattern,
the upper transistor includes a second semiconductor pattern, a second upper electrode disposed on the second semiconductor pattern, and a lower electrode disposed below the second semiconductor pattern,
the first semiconductor pattern and the second semiconductor pattern overlap, and
the conductive pattern at least partially overlaps each of the first semiconductor pattern and the second semiconductor pattern.

17. The electronic device of claim 16, wherein at least one of the first semiconductor pattern or the second semiconductor pattern comprises a metal oxide containing at least one of indium, gallium, zinc, tin, or titanium.

18. The electronic device of claim 16, wherein
the pixel circuit comprises a driving transistor including a third semiconductor pattern, and a switching transistor including a fourth semiconductor pattern that is distinguished from the third semiconductor pattern, and
at least one of the third semiconductor pattern or the fourth semiconductor pattern includes a metal oxide containing at least one of indium, gallium, zinc, tin, or titanium.

19. The electronic device of claim 18, wherein the first semiconductor pattern, the third semiconductor pattern, and the fourth semiconductor pattern are disposed on a same layer.

20. The electronic device of claim 18, wherein
the third semiconductor pattern and any one of the first semiconductor pattern or the second semiconductor pattern are disposed on a same layer,
the fourth semiconductor pattern overlaps the third semiconductor pattern and is disposed above or below the third semiconductor pattern, and
the circuit layer further comprises a pixel portion conductive pattern disposed between the third semiconductor pattern and the fourth semiconductor pattern.
